(19) United States
(12) Patent Application Publication
(10) Pub. No.: US 2024/0244905 A1
(43) Pub. Date: Jul. 18, 2024

(54) DISPLAY DEVICE AND METHOD FOR MANUFACTURING THE SAME

(71) Applicant: Samsung Display Co., LTD., Yongin-si (KR)

(72) Inventors: Jae Hak LEE, Yongin-si (KR); Si Joon SONG, Yongin-si (KR)

(21) Appl. No.: 18/396,676

(22) Filed: Dec. 26, 2023

(30) Foreign Application Priority Data
Jan. 18, 2023 (KR) 10-2023-0007529

(51) Int. Cl. H10K 59/131; H10K 59/12

(52) U.S. Cl. CPC H10K 59/131; H10K 59/1201; H10K 2102/341

(57) ABSTRACT

A display device includes a first substrate; a thin film transistor disposed on an upper surface of the first substrate; a plurality of pad electrodes disposed under a lower surface of the first substrate; a second substrate disposed under the lower surface of the first substrate and defining an opening therein exposing the plurality of pad electrodes; a circuit board attached onto the plurality of pad electrodes exposed through the opening of the second substrate; and a plurality of conductive ink patterns surrounding at least a side surface of the circuit board and being in contact with at least one of the plurality of pad electrodes, where lower surfaces of the plurality of conductive ink patterns each have a shape having a concave central portion.

This application claims priority to Korean Patent Application No. 10-2023-0007529 filed on Jan. 18, 2023, and all the benefits accruing therefrom under 35 U.S.C. 119, the contents of which in its entirety are herein incorporated by reference.

### BACKGROUND

### 1. Technical Field

The present disclosure relates to a display device and a method for manufacturing the same.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions.

The display devices may be flat panel display devices such as liquid crystal display devices, field emission display devices, or organic light emitting display devices. Among the flat panel display devices, the light emitting display device may include a light emitting element in which each of the pixels of a display panel may emit light by itself, thereby displaying an image without a backlight unit providing the light to the display panel.

The display device may include a display panel and a display driver for driving the display panel. The display driver may be formed of an integrated circuit chip or a circuit board and mounted on the display panel using a chip on glass (“COG”), chip on plastic (“COP”), and/or chip on film (“COF”) method. Such an integrated circuit chip or the like may be mounted on the display panel through a bonding process of heating and pressing using an anisotropic conductive film (“ACF”).

On the other hand, according to the market demand for miniaturization and high density of the display devices, various attempts have been made to reduce a dead space, which is an unnecessary area, when the integrated circuit chip or the like is mounted on the display panel.

In order to minimize the impact of heat and pressure applied during the bonding process to a display area of the display panel in the process of reducing the dead space, research on a new bonding method that does not apply heat and pressure is being conducted.

### SUMMARY

Aspects of the present disclosure provide a display device with a minimized dead space.

Aspects of the present disclosure also provide a method for manufacturing a display device capable of minimizing impact applied to a display panel.

Aspects of the present disclosure also provide a method for manufacturing a display device capable of minimizing an occurrence of a short circuit and maximizing manufacturing process efficiency.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device includes a first substrate, a thin film transistor disposed on an upper surface of the first substrate, a plurality of pad electrodes disposed under a lower surface of the first substrate, a second substrate disposed under the lower surface of the first substrate and defining an opening therein exposing the plurality of pad electrodes, a circuit board attached onto the plurality of pad electrodes exposed through the opening of the second substrate, and a plurality of conductive ink patterns surrounding at least a side surface of the circuit board and being in contact with at least one of the plurality of pad electrodes, wherein lower surfaces of the plurality of conductive ink patterns each have a shape having a concave central portion.

The circuit board may include a base and a bump disposed on the base, and one end portion of the bump may protrude from one end portion of the base.

The plurality of conductive ink patterns may cover at least a portion of the bump and the pad electrode, and electrically connect the bump and the pad electrode to each other.

The plurality of conductive ink patterns may completely cover lower and side surfaces of the bump.

The display device may further include a non-conductive film disposed between the bump and the pad electrode.

A width of each of the lower surfaces of the plurality of conductive ink patterns may be narrower than a width of each of upper surfaces of the plurality of conductive ink patterns.

Side surfaces of the plurality of conductive ink patterns may be inclined.

The display device may further include a barrier layer disposed between the first substrate and the second substrate, wherein the barrier layer may expose at least a portion of the pad electrode.

A lower surface of each of the pad electrodes may be hydrophilic, and the lower surface of the first substrate adjacent to the pad electrode may be hydrophobic.

The plurality of conductive ink patterns may be adjacent to each other along a first direction and alternately disposed in a second direction different from the first direction.

According to an aspect of the present disclosure, a method for manufacturing a display device includes: preparing a display panel and a circuit board, and forming a plurality of conductive ink patterns under the display panel and the circuit board by seating a mask defining a plurality of holes therein and dropping conductive ink into the plurality of holes. The display panel includes: a first substrate, a thin film transistor disposed on an upper surface of the first substrate, a plurality of pad electrodes disposed under a lower surface of the first substrate, and a second substrate disposed under the lower surface of the first substrate and defining an opening therein exposing the plurality of pad electrodes, wherein the circuit board is attached onto the plurality of pad electrodes exposed through the opening of the second substrate, the plurality of conductive ink patterns surround at least a side surface of the circuit board and is in contact with at least one of the plurality of pad electrodes, and lower surfaces of the plurality of conductive ink patterns each have a shape having a concave central portion.

The forming of the conductive ink patterns may include: applying the conductive ink on the mask, and pushing the conductive ink into the plurality of holes using a blade.

The forming of the conductive ink patterns may include: interposing a conductive ball in the plurality of holes, and melting and dropping the conductive ball in the form of the conductive ink by irradiating the conductive ball with a laser.

The mask may include a first surface positioned on one side of the plurality of holes and a second surface positioned on the other side of the plurality of holes, and a vertical length of the first surface is shorter than a vertical length of the second surface.

A vertical-length difference between the vertical length of the first surface and the vertical length of the second surface may be equal to a height difference between a lower surface of the circuit board and a lower surface of the first substrate.

The plurality of holes may be adjacent to each other along a first direction and alternately disposed in a second direction different from the first direction.

Each of the plurality of holes may have a wider width in a direction from top to bottom thereof.

A boundary of a bottom end portion of the mask may coincide with a boundary of the opening.

The conductive ink may include at least one of silver (Ag) nanoparticle ink, copper (Cu) nanoparticle ink, and metal organic decomposition ink.

The conductive ink may have a metal content of 50 weight percents (wt %) to 90 wt %.

According to the display device according to an embodiment of the present disclosure, the dead space may be effectively minimized.

According to the method for manufacturing the display device according to an embodiment of the present disclosure, the impact applied to the display panel during the bonding process may be effectively minimized.

According to the method for manufacturing the display device according to another embodiment of the present disclosure, the occurrence of short circuit may be effectively minimized and the manufacturing process efficiency may be effectively maximized.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device according to an embodiment;

FIG. 2 is a plan view illustrating a lower surface of the display device according to an embodiment;

FIG. 3 is a cross-sectional view taken along line I-I′ of FIG. 2;

FIG. 4 is a plan view illustrating lines of the display device according to an embodiment;

FIG. 5 is a cross-sectional view illustrating a portion of a display area of the display device according to an embodiment;

FIG. 6 is a cross-sectional view illustrating portions of a display area and a non-display area of the display device according to an embodiment;

FIGS. 7A and 7B are side views of a circuit board according to an embodiment;

FIG. 8 is an enlarged view of part ‘A’ of FIG. 2;

FIG. 9 is a cross-sectional view taken along line II-II′ of FIG. 2;

FIG. 10 is an enlarged view of part ‘B’ of FIG. 6;

FIG. 11 is a plan view illustrating a lower surface of a display panel according to another embodiment;

FIG. 12 is a cross-sectional view taken along line III-III′ of FIG. 11;

FIG. 13 is a plan view illustrating a lower surface of a display device according to still another embodiment;

FIG. 14 is a plan view illustrating a lower surface of a display device according to still another embodiment;

FIG. 15 is a cross-sectional view taken along line IV-IV′ of FIG. 14;

FIGS. 16A, 16B, and 16C are flowcharts illustrating a method for manufacturing a display device according to an embodiment;

FIGS. 17 and 18 are a plan view and a cross-sectional view illustrating step S110 of FIG. 16B, respectively;

FIGS. 19 and 20 are a plan view and a cross-sectional view illustrating step S120 of FIG. 16B, respectively;

FIGS. 21 and 22 are a plan view and a cross-sectional view illustrating step S130 of FIG. 16B, respectively;

FIGS. 23 and 24 are a plan view and a cross-sectional view illustrating step S210 of FIG. 16C, respectively;

FIG. 25 is a perspective view illustrating a mask used in the method for manufacturing a display device according to an embodiment;

FIGS. 26A and 26B are a plan view and a cross-sectional view illustrating the mask used in the method for manufacturing a display device according to an embodiment, respectively;

FIGS. 27 and 28 are a plan view and a cross-sectional view illustrating step S220 of FIG. 16C, respectively;

FIGS. 29 and 30 are a plan view and a cross-sectional view illustrating step S230 of FIG. 16C, respectively;

FIG. 31 is a cross-sectional view illustrating step S220 in a method for manufacturing a display device according to another embodiment;

FIG. 32 is a plan view illustrating step S210 in a method for manufacturing a display device according to still another embodiment;

FIG. 33 is a plan view illustrating a mask of FIG. 32;

FIG. 34 is a cross-sectional view illustrating step S210 in the method for manufacturing a display device according to still another embodiment;

FIG. 35 is a plan view illustrating step S210 in the method for manufacturing a display device according to still another embodiment; and

FIG. 36 is a cross-sectional view illustrating step S210 in the method for manufacturing a display device according to an embodiment.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “under,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “under” other elements or features would then be oriented “above” the other elements or features. Thus, the term “under” can encompass both an orientation of above and under. The device may be otherwise oriented (rotated 90 degrees or at other orientations) and the spatially relative descriptors used herein interpreted accordingly.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein. Hereinafter, specific embodiments will be described with reference to the accompanying drawings.

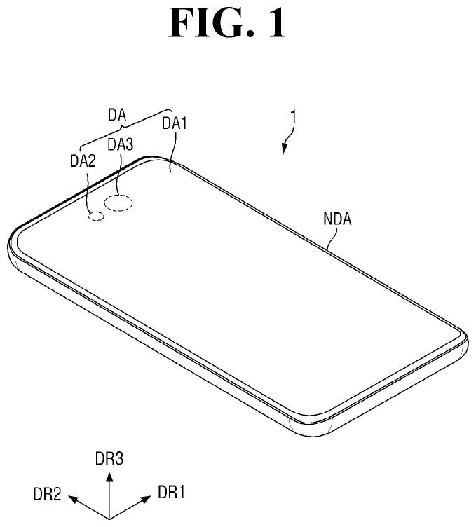

FIG. 1 is a perspective view of a display device according to an embodiment.

Referring to FIG. 1, a display device 1 may provide a display screen for displaying moving images or still images. Examples of the display device 1 may include an inorganic light emitting diode display device, an organic light emitting diode display device, a quantum dot light emitting display device, a plasma display device, and a field emission display device. Hereinafter, it is illustrated that an organic light emitting diode display device is used as an example of the display device 1, but the present disclosure is not limited thereto. Any display device may also be used as long as the same technical idea is applicable.

A shape of the display device 1 may be variously changed. For example, the display device 1 may have a shape such as a rectangle with a long width, a rectangle with a long length, a square, a quadrangle with rounded corners (vertices), other polygons, or a circle. In FIG. 1, the display device 1 of a rectangular shape having a short side in a first direction DR1 and a long side in a second direction DR2 is illustrated.

In the illustrated drawings, the first direction DR1 and the second direction DR2 are horizontal directions and intersect each other. For example, the first direction DR1 and the second direction DR2 may be orthogonal to each other. In addition, a third direction DR3 may be a vertical direction intersecting the first direction DR1 and the second direction DR2, for example, orthogonal to the first direction DR1 and the second direction DR2. In the present specification, directions indicated by arrows in the first to third directions DR1, DR2, and DR3 may be referred to as one side, and the opposite direction thereof may be referred to as the other side.

The display device 1 may include a display area DA and a non-display area NDA. The display area DA is an area in which a screen may be displayed, and the non-display area NDA is an area in which a screen is not displayed. The display area DA may also be referred to as an active area, and the non-display area NDA may also be referred to as a non-active area. The display area DA may generally occupy the center of the display device 1.

A shape of the display area DA may be similar to an overall shape of the display device 1. The display area DA may include a first display area DA1, a second display area DA2, and a third display area DA3. The second display area DA2 and the third display area DA3, which are areas in which components for adding various functions to the display device 1 are disposed, may correspond to component areas.

The display area DA may emit light from a plurality of light emitting areas or a plurality of opening areas. For example, the display panel 100 may include a pixel circuit including switching elements, a pixel defining film defining the light emitting areas or the opening areas, and a self-light emitting element.

For example, the self-light emitting element may include at least one of an organic light emitting diode (“LED”) including an organic light emitting layer, a quantum dot LED including a quantum dot light emitting layer, an inorganic LED including an inorganic semiconductor, and a micro LED, but is not limited thereto.

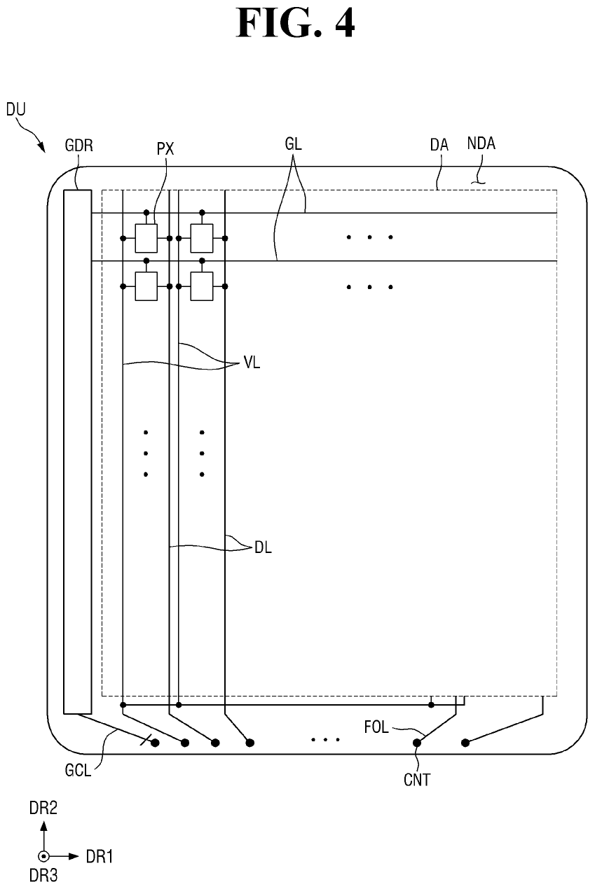

The non-display area NDA may be an area outside the display area DA. The non-display area NDA may be defined as an edge area of the display device 1. The non-display area NDA may include a gate driver GDR (see FIG. 4) supplying gate signals to gate lines, and fan-out lines FOL (see FIG. 4) connecting a contact hole CNT (see FIG. 4) and the display area DA to each other.

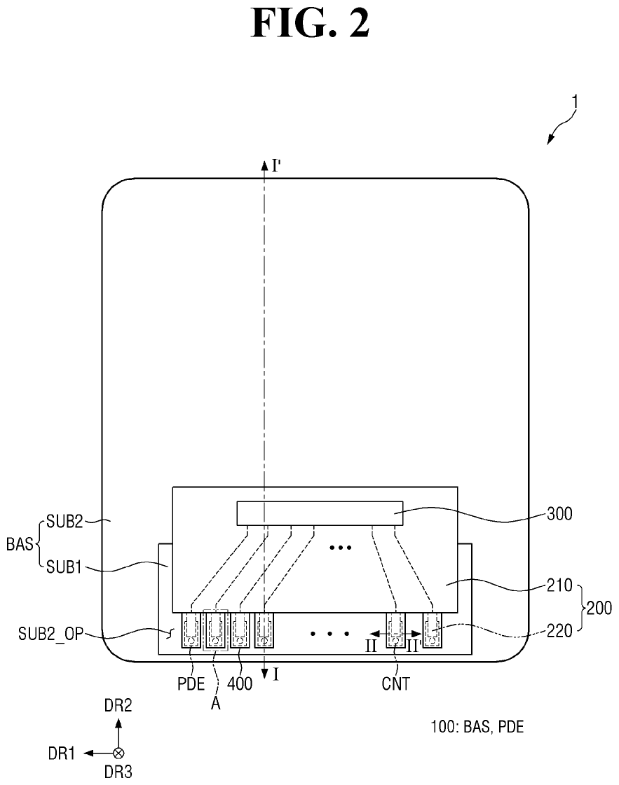

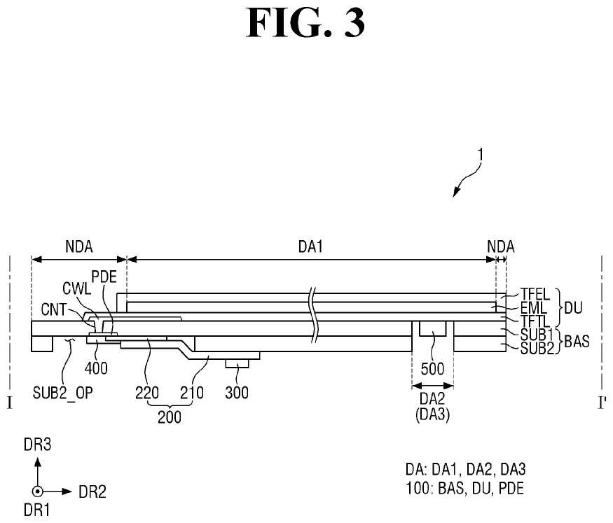

FIG. 2 is a plan view illustrating a lower surface of the display device according to an embodiment. FIG. 3 is a cross-sectional view taken along line I-I′ of FIG. 2.

Referring to FIGS. 2 and 3, the display device 1 according to an embodiment may include a display panel 100, a circuit board 200, a driving chip 300, and a conductive ink pattern 400.

The display panel 100 may include a base member BAS, a display layer DU, and a plurality of pad electrodes PDE.

The base member BAS may include a first substrate SUB1 and a second substrate SUB2 disposed on the other surface of the first substrate SUB1. The second substrate SUB2 may be disposed on a lower side of the first substrate SUB1. Sizes of the first substrate SUB1 and the second substrate SUB2 may be substantially the same, but are not limited thereto, and the size of the second substrate SUB2 disposed on the lower side of the first substrate SUB1 may also be greater than the size of the first substrate SUB1. The first substrate SUB1 may be exposed through an opening SUB2_OP of the second substrate SUB2, which will be described later.

The first substrate SUB1 may be a flexible substrate that may be bent, folded, or rolled. For example, the first substrate SUB1 may include a polymer resin such as polyimide PI, but is not limited thereto. In another embodiment, the first substrate SUB1 may be a rigid substrate including a glass material or a metal material.

In some embodiments, the first substrate SUB1 may be disposed on an entire surface of the display device 1. For example, the first substrate SUB1 may be integrally formed across the display area DA and the non-display area NDA.

The first substrate SUB1 may include a plurality of contact holes CNT penetrating from an upper surface thereof. For example, the contact hole CNT may penetrate from the upper surface of the first substrate SUB1 to the lower surface thereof. The contact hole CNT may be a through-hole into which a connection line CWL is inserted therein. The plurality of contact holes CNT may be disposed to overlap the plurality of pad electrodes PDE, respectively.

Herein, an “upper surface” of each member of the display device 1 may refer to a surface facing a direction (i.e., the third direction DR3) in which the light emitted from the light emitting element transmits to the outside of the display device 1. All the upper surfaces of the members of the display devices 1 may face the same direction. One of the upper surfaces may provide the display screen for displaying the moving images or still images. A “lower surface” of each member may refer to a surface opposite to the upper surface.

In some embodiments, the plurality of contact holes CNT may be arranged side by side on a straight line extending along the first direction DR1 as illustrated in FIG. 2. However, the plurality of contact holes CNT are not limited thereto, and may also be alternately disposed along the second direction DR2 with adjacent contact holes CNT along the first direction DR1.

In an embodiment, as illustrated in FIG. 3, the contact hole CNT may be disposed to overlap the non-display area NDA, but to be adjacent to the display area DA. In another embodiment, the contact hole CNT may be disposed to overlap the display area DA. Accordingly, as the pad electrode PDE connected to the connection line CWL of the thin film transistor layer TFTL through the contact hole CNT is disposed to be adjacent to or to overlap the display area DA, a bezel area or dead space of the display device 1 may be minimized.

The second substrate SUB2 may be made of the same material as the first substrate SUB1. Like the first substrate SUB1, the second substrate SUB2 may be a flexible substrate that may be bent, folded, or rolled. For example, the second substrate SUB2 may include a polymer resin such as polyimide PI, but is not limited thereto. In another embodiment, the second substrate SUB2 may be a rigid substrate including a glass material or a metal material.

The second substrate SUB2 may be disposed on the other surface of the first substrate SUB1. For example, as illustrated in the drawing, the second substrate SUB2 may be disposed on the other side of the first substrate SUB1, that is, on a lower side of the first substrate SUB1, with respect to the third direction DR3.

In some embodiments, the second substrate SUB2 may be disposed on an entire surface of the display device 1. For example, the second substrate SUB2 may be integrally formed across the display area DA and the non-display area NDA.

The second substrate SUB2 may define an opening SUB2_OP therein exposing the pad electrode PDE. For example, the opening SUB2_OP may penetrate from a lower surface to an upper surface of the second substrate SUB2. The opening SUB2_OP may have a rectangular parallelepiped shape extending along the first and second directions DR1 and DR2, but is not limited thereto.

The opening SUB2_OP may be disposed to overlap the plurality of pad electrodes PDE. At least a portion of the base 210 of the circuit board 200, the bump 220, the pad electrode PDE and the conductive ink pattern 400 disposed on the bump 220 may be positioned within the opening SUB2_OP.

In some embodiments, the opening SUB2_OP may be disposed to overlap the non-display area NDA and the display area DA. However, the opening SUB2_OP is not limited thereto and may also be disposed to overlap only one of the non-display area NDA and the display area DA.

The display layer DU may be disposed on the base member BAS. The display layer DU may be disposed on one surface of the first substrate SUB1. For example, as illustrated in the drawing, the display layer DU may be disposed on one side of the first substrate SUB1, that is, on an upper side of the first substrate SUB1, with respect to the third direction DR3.

The display layer DU may include a thin film transistor layer TFTL, a light emitting element layer EML, and a thin film encapsulation layer TFEL.

The thin film transistor layer TFTL may be disposed on the base member BAS. The thin film transistor layer TFTL may be disposed on one surface of the first substrate SUB1. For example, as illustrated in the drawing, the thin film transistor layer TFTL may be disposed on one side of the first substrate SUB1, that is, on an upper side of the first substrate SUB1, with respect to the third direction DR3.

The thin film transistor layer TFTL may include a plurality of thin film transistors constituting a pixel circuit of pixels. The thin film transistor layer TFTL may include gate lines GL, data lines DL, power lines VL, gate control lines GCL, and fan-out lines FOL connecting the contact holes CNT and the data lines DL that are illustrated in FIG. 4. Each of the thin film transistors may include a semiconductor area, a source electrode, a drain electrode, and a gate electrode. For example, when the gate driver is formed on one side of the non-display area NDA of the display panel 100, the gate driver may include the thin film transistors.

The thin film transistor layer TFTL may be disposed in the display area DA and the non-display area NDA. The thin film transistors of each of the pixels, the gate lines GL, the data lines DL, and the power lines VL of the thin film transistor layer TFTL may be disposed in the display area DA. The gate control lines GCL and the fan-out lines FOL of the thin film transistor layer TFTL may be disposed in the non-display area NDA.

The thin film transistor layer TFTL may include the connection line CWL inserted into the contact hole CNT. The connection line CWL may be a connection line that is inserted into the contact hole CNT to connect the thin film transistor layer TFTL disposed on one surface of the first substrate SUB1 and the pad electrode PDE disposed on the other surface of the first substrate SUB1. The connection line CWL may provide an electrical signal received from the pad electrode PDE to the thin film transistor layer TFTL.

The light emitting element layer EML may be disposed on the thin film transistor layer TFTL. The light emitting element layer EML may include a plurality of light emitting elements including a first electrode, a second electrode, and a light emitting layer to emit light, and a pixel defining film defining pixels. The plurality of light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL and the second electrode receives a cathode voltage, holes and electrons may move to the organic light emitting layer through the hole transporting layer and the electron transporting layer, respectively, and may be combined with each other in the organic light emitting layer to emit light.

In another embodiment, the light emitting element may include a quantum dot light emitting diode including a quantum dot light emitting layer, an inorganic light emitting diode including an inorganic semiconductor, or a micro light emitting diode.

The thin film encapsulation layer TFEL may cover an upper surface and side surfaces of the light emitting element layer EML, and may protect the light emitting element layer EML. The thin film encapsulation layer TFEL may include at least one inorganic film and at least one organic film for encapsulating the light emitting element layer EML.

The plurality of pad electrodes PDE may be disposed on the other surface of the first substrate SUB1. For example, as illustrated in the drawing, the pad electrode PDE may be disposed on the other side of the first substrate SUB1, that is, on the lower side of the first substrate SUB1, with respect to the third direction DR3.

In some embodiments, the plurality of pad electrodes PDE may be arranged side by side on a straight line extending along the first direction DR1 as illustrated in FIG. 2. However, the plurality of pad electrodes PDE are not limited thereto, and may also be alternately disposed along the second direction DR2 with the pad electrodes PDE adjacent to each other along the first direction DR1.

In an embodiment, as illustrated in FIG. 3, the pad electrode PDE may be disposed to overlap the non-display area NDA, but to be adjacent to the display area DA. In another embodiment, the pad electrode PDE may be disposed to overlap the display area DA. Accordingly, the bezel area or dead space of the display device 1 may be minimized.

The pad electrode PDE may be electrically connected to the bump 220 of the circuit board 200 through the conductive ink pattern 400. The pad electrode PDE may receive various voltages or signals from the circuit board 200 and may provide the corresponding voltages or signals to the connection line CWL.

When a barrier layer BAR, which will be described later, is not included, the pad electrode PDE and the first substrate SUB1 may at least partially share the same plane of which the normal direction is the third direction DR3. The pad electrode PDE may be surrounded by the first substrate SUB1.

The circuit board 200 may be disposed on the other surface of the first substrate SUB1. For example, as illustrated in the drawing, the circuit board 200 may be disposed on the other side of the first substrate SUB1, that is, on the lower side of the first substrate SUB1, with respect to the third direction DR3.

The circuit board 200 may be a flexible film such as a flexible printed circuit board, a printed circuit board, or a chip on film.

The circuit board 200 may include a base 210 and a bump 220 disposed on the base 210.

The base 210 may be a base substrate or a base member. The base 210 may be a flexible substrate that may be bent, folded, rolled, or the like. For example, the base 210 may include a polymer resin such as polyimide PI, but is not limited thereto. In another embodiment, the base 210 may include a glass material or a metal material.

The bump 220 may include a conductive material. As an example, the bump 220 may be a protruding electrode protruding in an upward direction from an upper surface of the base 210.

The bump 220 may be disposed on the base 210. As an example, the bump 220 may be disposed on a upper side of the base 210. As illustrated in FIG. 3, the bump 220 may be disposed on one side of the base 210 with respect to the third direction DR3, that is, on an upper side of the base 210 in the drawing.

In some embodiments, an interval between a plurality of bumps 220 adjacent to each other and an interval between a plurality of pad electrodes PDE adjacent to each other may be the same. The interval between the plurality of bumps 220 adjacent to each other and the interval between the plurality of pad electrodes PDE adjacent to each other may refer to an interval between central portions of the bumps 220 and the pad electrodes PDE.

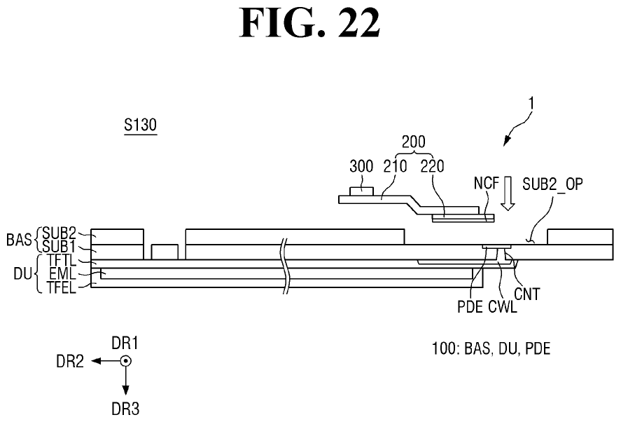

At least a portion of the bump 220 may be disposed on the pad electrode PDE. Although not illustrated, the bump 220 may be attached onto the pad electrode PDE and the first substrate SUB1 through a non-conductive film NCF (see FIG. 22).

One end portion of the bump 220 may more protrude than one end portion of the base 210. For example, the other end portion of the bump 220 in the second direction DR2 may protrude toward the non-display area NDA more than the other end portion of the base 210 in the second direction DR2. At least a portion of the protruding portion of the bump 220 may be disposed on the pad electrode PDE.

One surface of the circuit board 200 may be attached to the pad electrode PDE through the bump 220, and the driving chip 300 may be mounted on the other surface of the circuit board 200.

The driving chip 300 may output signals and voltages for driving the display panel 100. The driving chip 300 may supply data voltages to the data lines. The driving chip 300 may supply a power voltage to the power line and may supply a gate control signal to the gate driver. The driving chip 300 may be formed as an integrated circuit (“IC”) and mounted on the display panel 100 by a chip on glass (COG) method, a chip on plastic (COP) method, or an ultrasonic bonding method.

The driving chip 300 may provide signals and voltages for driving the display panel 100 to the bump 220 and the pad electrode PDE connected to the bump 220 through lines disposed on and/or inside the base 210 of the circuit board 200.

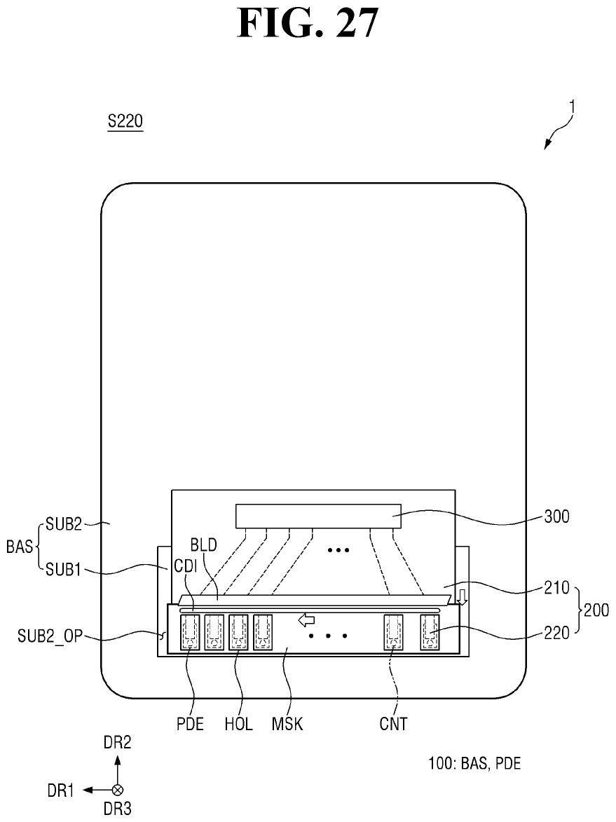

The conductive ink pattern 400 may attach and fix the circuit board 200 to the pad electrode PDE. The conductive ink pattern 400 may be formed by sintering conductive ink CDI (see FIG. 27) in a bonding process of a display device 1, which will be described later. The conductive ink pattern 400 may include a material included in the conductive ink CDI. For example, the conductive ink pattern 400 may include a conductive metal material. The conductive ink pattern 400 may include at least one of silver (Ag) nanoparticle ink, copper (Cu) nanoparticle ink, and metal organic decomposition ink.

The conductive ink pattern 400 may have high electrical conductivity. As an example, when the conductive ink pattern 400 has a width of 0.1 mm and a length of 1 mm at room temperature, a resistance value of the conductive ink pattern 400 may be 0.5Ω or less.

The conductive ink pattern 400 may be disposed on the bump 220 and the pad electrode PDE. The conductive ink pattern 400 may be in direct contact with the bump 220 and the pad electrode PDE. The conductive ink pattern 400 may electrically connect the bump 220 and the pad electrode PDE to each other. In an embodiment, the conductive ink pattern 400 may be in direct contact with the first substrate SUB1 or a barrier layer BAR to be described later, but is not limited thereto.

In some embodiments, the conductive ink pattern 400 may completely cover upper and side surfaces of the bump 220 and the pad electrode PDE. As a result, a contact area of the conductive ink pattern 400 with the bump 220 and the pad electrode PDE increases, thereby increasing adhesion.

It is illustrated in the drawing that the conductive ink pattern 400 does not cover the lower surface of the base 210, but the conductive ink pattern 400 is not limited thereto. In some embodiments, the conductive ink pattern 400 may also cover the lower surface of the base 210. In this case, the lower surface of the conductive ink pattern 400 may be positioned to be lower than the lower surface of the base 210.

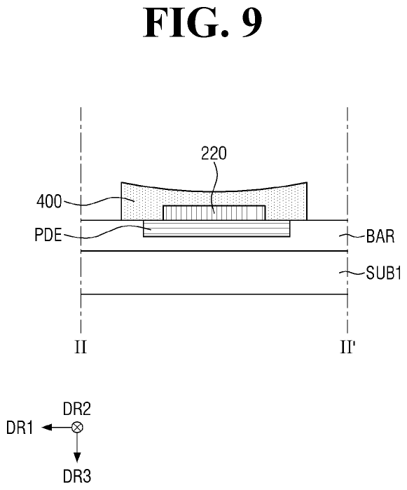

A shape of the conductive ink pattern 400 will be described later with reference to FIG. 9 and the like.

In some embodiments, the display device 1 may further include an optical device 500. The optical device 500 may be disposed in the second display area DA2 and/or the third display area DA3. The optical device 500 may emit or receive light in infrared, ultraviolet, and visible light bands. For example, the optical device 500 may be an optical sensor that detects light incident on the display device 1, such as a proximity sensor, an illuminance sensor, and a camera sensor or an image sensor.

FIG. 4 is a plan view illustrating lines of the display device according to an embodiment.

Referring to FIG. 4, the display layer DU may include a display area DA and a non-display area NDA.

The display area DA may be disposed at the center of the display panel 100. A plurality of pixels PX, a plurality of gate lines GL, a plurality of data lines DL, and a plurality of power lines VL may be disposed in the display area DA. Each of the plurality of pixels PX may be defined as a minimum unit emitting light.

The plurality of gate lines GL may supply the gate signal received from the gate driver GDR to the plurality of pixels PX. The plurality of gate lines GL may extend in the first direction DR1 and may be spaced apart from each other in the second direction DR2 intersecting the first direction DR1.

The plurality of data lines DL may supply the data voltage received from the driving chip 300 to the plurality of pixels PX. The plurality of data lines DL may extend in the second direction DR2 and may be spaced apart from each other in the first direction DR1.

The plurality of power lines VL may supply the power voltage received from the driving chip 300 to the plurality of pixels PX. Here, the power voltage may be at least one of a driving voltage, an initialization voltage, a reference voltage, and a low potential voltage. The plurality of power lines VL may extend in the second direction DR2 and may be spaced apart from each other in the first direction DR1.

The non-display area NDA may surround the display area DA. The gate driver GDR, the fan-out lines FOL, and the gate control lines GCL may be disposed in the non-display area NDA. The gate driver GDR may generate a plurality of gate signals based on the gate control signal, and may sequentially supply the plurality of gate signals to the plurality of gate lines GL according to a set order.

The fan-out lines FOL may extend from the contact holes CNT to the display area DA. The fan-out lines FOL may supply the data voltage received from the driving chip 300 via the contact hole CNT, the pad electrode PDE, and the circuit board 200 to the plurality of data lines DL. As an example, the fan-out lines FOL may include the connection line CWL described with reference to FIG. 3.

It is illustratively illustrated in the drawing that the fan-out lines FOL are connected to the data lines DL, but the fan-out lines FOL are not limited thereto and may also be connected to the gate lines GL.

The gate control line GCL may extend from the contact hole CNT to the gate driver GDR. The gate control line GCL may supply the gate control signal received from the driving chip 300 via the contact hole CNT, the pad electrode PDE, and the circuit board 200 to the gate driver GDR. As an example, the gate control line GCL may include the connection line CWL described with reference to FIG. 3.

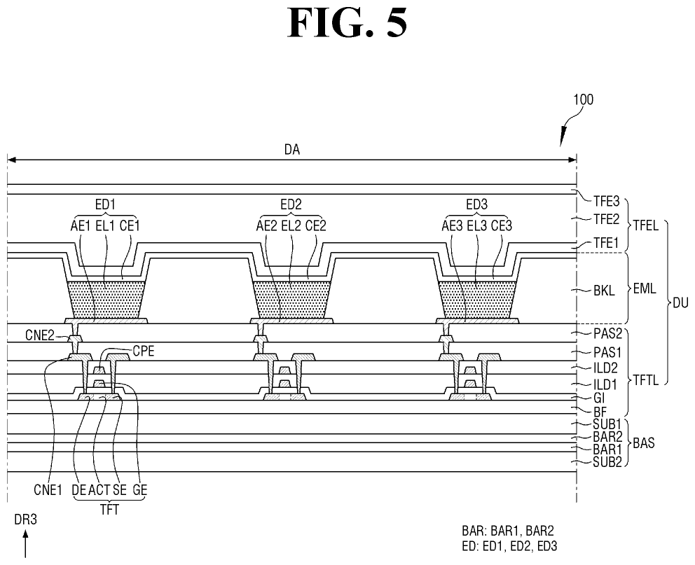

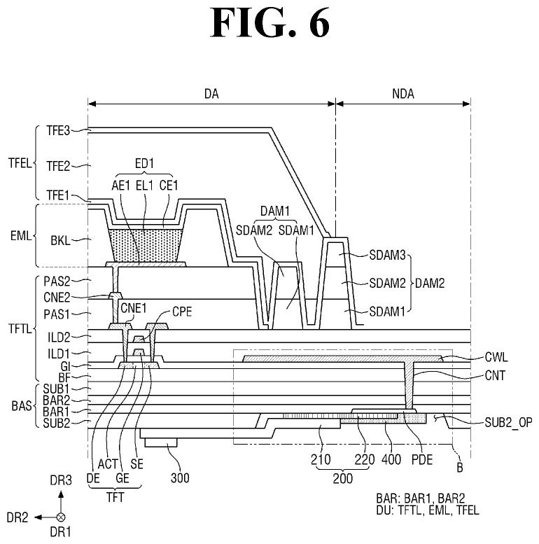

FIG. 5 is a cross-sectional view illustrating a portion of a display area of the display device according to an embodiment. FIG. 6 is a cross-sectional view illustrating portions of a display area and a non-display area of the display device according to an embodiment.

Referring to FIGS. 5 and 6, the display device 1 according to an embodiment may include a display panel 100, a circuit board 200, a driving chip 300, and a conductive ink pattern 400.

The display panel 100 may include a base member BAS, a display layer DU, and a plurality of pad electrodes PDE.

The base member BAS may include a first substrate SUB1, a second substrate SUB2 disposed on the other surface of the first substrate SUB1, and a barrier layer BAR disposed between the first substrate SUB1 and the second substrate SUB2.

Since the first substrate SUB1 and the second substrate SUB2 are described with reference to FIG. 2 and the like, the descriptions thereof will be omitted.

The barrier layer BAR may be disposed between the first substrate SUB1 and the second substrate SUB2. The barrier layer BAR may include an inorganic material capable of preventing permeation of air or moisture. For example, the barrier layer BAR may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

In some embodiments, the barrier layer BAR may include a plurality of layers. As an example, the barrier layer BAR may include a first barrier layer BAR1 and a second barrier layer BAR2 as illustrated in the drawing.

The first barrier layer BAR1 may be disposed between the second barrier layer BAR2 and the second substrate SUB2. The first barrier layer BAR1 may cover the second substrate SUB2 and the pad electrode PDE. The first barrier layer BAR1 may define an opening therein exposing a lower surface of the pad electrode PDE. The first barrier layer BAR1 may define a contact hole CNT therein exposing the upper surface of the pad electrode PDE to be in contact with the connection line CWL.

The second barrier layer BAR2 may be disposed between the first barrier layer BAR1 and the first substrate SUB1. The second barrier layer BAR2 may include a contact hole CNT into which the connection line CWL may be inserted.

In some embodiments, the first barrier layer BAR1 and the second barrier layer BAR2 may be omitted. Hereinafter, a case in which the first barrier layer BAR1 and the second barrier layer BAR2 are included will be described as an example.

The display layer DU may include a thin film transistor layer TFTL, a light emitting element layer EML, and a thin film encapsulation layer TFEL.

The thin film transistor layer TFTL may include a buffer layer BF, a thin film transistor TFT, a gate insulating layer GI, a connection line CWL, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The buffer layer BF may be disposed on the first substrate SUB1. The buffer layer BF may include an inorganic film capable of preventing permeation of air or moisture. The buffer layer BF may include a contact hole CNT into which the connection line CWL may be inserted. In some embodiments, the buffer layer BF may have a structure of a single film or a plurality of stacked films.

In some embodiments, a lower metal layer may be further disposed on the buffer layer BF. The lower metal layer may include a material that blocks light to prevent light from being incident on a semiconductor layer ACT. In another embodiment, when some of the thin film transistors TFT include low temperature polycrystalline oxide (“LTPO”) thin film transistors, the lower metal layer may be positioned on an upper side of a layer where a gate electrode GE is positioned. For example, the lower metal layer may also be positioned between the gate electrode GE and the first interlayer insulating layer ILD1, which will be described later.

The thin film transistor TFT may be disposed on the buffer layer BF, and may constitute a pixel circuit of each of the plurality of pixels PX. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The gate insulating layer GI may be disposed on the semiconductor layer ACT. The gate insulating layer GI may insulate the semiconductor layer ACT and the gate electrode GE from each other. The gate insulating layer GI may include a contact hole through which the first connection electrode CNE1 penetrates. The gate insulating layer GI may include a contact hole CNT into which the connection line CWL may be inserted.

The gate electrode GE may be disposed on the gate insulating layer GI. The gate electrode GE may overlap the semiconductor layer ACT with the gate insulating layer GI interposed therebetween.

The first interlayer insulating layer ILD1 may cover the gate electrode GE and the gate insulating layer GI. The first interlayer insulating layer ILD1 may include a contact hole through which the first connection electrode CNE1 penetrates. The contact hole of the first interlayer insulating layer ILD1 may be connected to the contact hole of the gate insulating layer GI and a contact hole of the second interlayer insulating layer ILD2.

In some embodiments, the connection line CWL may be disposed on the gate insulating layer GI. The connection line CWL may be inserted into the contact hole CNT penetrating through the gate insulating layer GI, the buffer layer BF, the first substrate SUB1, the second barrier layer BAR2, and the first barrier layer BAR1. The connection line CWL may be disposed on the same layer as the gate electrode GE and may include the same material as the gate electrode GE.

It is illustrated as an example in the drawing that the connection line CWL is disposed on the gate insulating layer GI, but the connection line CWL is not limited thereto. In another embodiment, the connection line CWL may also be disposed on the buffer layer BF. In this case, the connection line CWL may also be inserted into a contact hole CNT penetrating through the buffer layer BF, the first substrate SUB1, the second barrier layer BAR2, and the first barrier layer BAR1. The connection line CWL may be disposed on the same layer as the semiconductor layer ACT and may include the same material as the semiconductor layer ACT.

The capacitor electrode CPE may be disposed on the first interlayer insulating layer ILD1. The capacitor electrode CPE and the gate electrode GE may form a capacitor.

The second interlayer insulating layer ILD2 may cover the capacitor electrode CPE and the first interlayer insulating layer ILD1. The second interlayer insulating layer ILD2 may include a contact hole through which the first connection electrode CNE1 penetrates. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the thin film transistor TFT and the second connection electrode CNE2 to each other through the contact holes formed in the second interlayer insulating layer ILD2, the first interlayer insulating layer ILD1, and the gate insulating layer GI.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 penetrates.

The second connection electrode CNE2 may be disposed on the first passivation layer PAS1. The second connection electrode CNE2 may electrically connect the first connection electrode CNE1 and pixel electrodes AE1, AE2, and AE3 of a light emitting element ED to each other through the contact hole formed in the first passivation layer PAS1.

The second passivation layer PAS2 may cover the second connection electrode CNE2 and the first passivation layer PAS1. The second passivation layer PAS2 may include contact holes through which the pixel electrodes AE1, AE2, and AE3 of the light emitting element ED penetrate.

The light emitting element layer EML may be disposed on the thin film transistor layer TFTL. The light emitting element layer EML may include a light emitting element ED and a bank layer BKL. The light emitting element ED may include pixel electrodes AE1, AE2, and AE3, light emitting layers EL1, EL2, and EL3, and common electrodes CE1, CE2, and CE3 as light emitting elements ED1, ED2, and ED3.

The pixel electrodes AE1, AE2, and AE3 may be disposed on the second passivation layer PAS2. The pixel electrodes AE1, AE2, and AE3 may be electrically connected to the drain electrode DE of the thin film transistor TFT through the first and second connection electrodes CNE1 and CNE2.

The light emitting layers EL1, EL2, and EL3 may be disposed on the pixel electrodes AE1, AE2, and AE3. In an embodiment, the light emitting layers EL1, EL2, and EL3 may be organic light emitting layers made of organic materials. In another embodiment, the light emitting elements ED1, ED2, and ED3 may include a quantum dot light emitting diode including a quantum dot light emitting layer, an inorganic light emitting diode including an inorganic semiconductor, or a micro light emitting diode.

The common electrodes CE1, CE2, and CE3 may be disposed on the light emitting layers EL1, EL2, and EL3. The common electrodes CE1, CE2, and CE3 may receive a common voltage or a low potential voltage.

The bank layer BKL may be disposed on the thin film transistor layer TFTL or the first substrate SUB1. The bank layer BKL may include an opening disposed for each pixel PX. The opening of the bank layer BKL may partition a light emitting area of each of the light emitting elements ED1, ED2, and ED3.

The thin film encapsulation layer TFEL may be disposed on the light emitting elements ED1, ED2, and ED3 and the bank layer BKL, and may cover the plurality of light emitting elements ED1, ED2, and ED3 and the bank layer BKL. The thin film encapsulation layer TFEL may include at least one inorganic film to prevent oxygen or moisture from permeating into the light emitting element layer EML. The thin film encapsulation layer TFEL may include at least one organic film to protect the light emitting element layer EML from foreign substances such as dust.

In an embodiment, the thin film encapsulation layer TFEL may include a first encapsulation layer TFE1, a second encapsulation layer TFE2, and a third encapsulation layer TFE3 that are sequentially stacked the first encapsulation layer TFE1 and the third encapsulation layer TFE3 may be inorganic encapsulation layers, and the second encapsulation layer TFE2 disposed therebetween may be an organic encapsulation layer.

The display panel 100 may include a first dam DAM1 and a second dam DAM2 disposed adjacent to or within the non-display area NDA. The first dam DAM1 and the second dam DAM2 may prevent the second encapsulation layer TFE2 of the thin film encapsulation layer TFEL from overflowing into the non-display area NDA. In an embodiment, the first dam DAM1 may include a first sub-dam SDAM1 and a second sub-dam SDAM2, and the second dam DAM2 may include a first sub-dam SDAM1, a second sub-dam SDAM2, and a third sub-dam SDAM3.

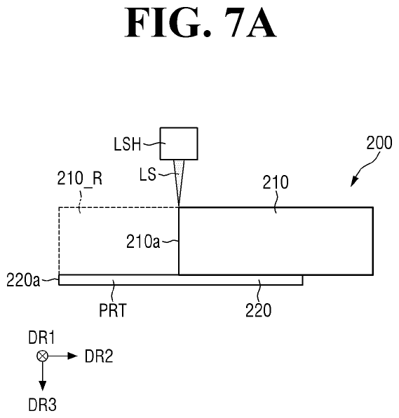

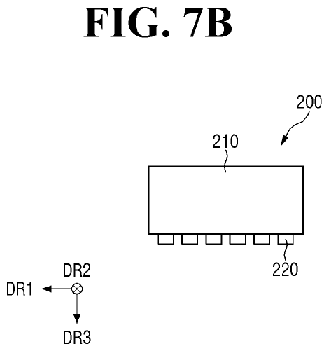

The pad electrode PDE, the circuit board 200, and the conductive ink pattern 400 will be described with reference to FIGS. 7A to 10 below.

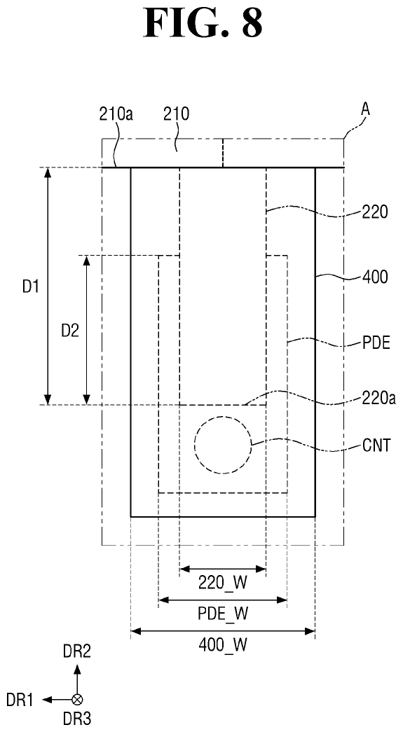

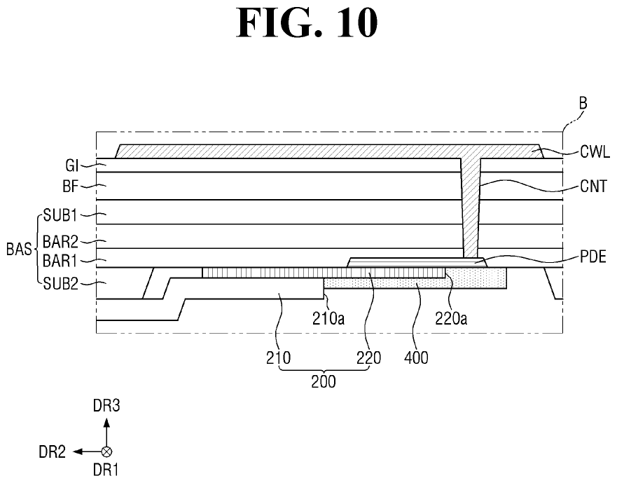

FIGS. 7A and 7B are side views of a circuit board according to an embodiment. FIG. 8 is an enlarged view of part ‘A’ of FIG. 2. FIG. 9 is a cross-sectional view taken along line II-II′ of FIG. 2. FIG. 10 is an enlarged view of part ‘B’ of FIG. 6. FIG. 7A is a side view of the circuit board 200 viewed from the first direction DR1, and FIG. 7B is a side view of the circuit board 200 viewed from the second direction DR2. FIGS. 7A, 7B and 9 are upside-down views.

Referring to FIGS. 7A to 10, the pad electrode PDE and the barrier layer BAR may at least partially share the same plane of which the normal direction is the third direction DR3. The pad electrode PDE may be surrounded by the barrier layer BAR. For example, the pad electrode PDE may be surrounded by the first barrier layer BAR1 and disposed on a lower side of the second barrier layer BAR2. The lower surface of the pad electrode PDE, that is, the other side surface thereof in the third direction DR3, may be positioned at the same level as a lower surface of the first barrier layer BAR1. At least a portion of the lower surface of the pad electrode PDE may be exposed to the opening SUB2_OP of the second substrate SUB2 through the opening of the first barrier layer BAR1. The pad electrode PDE exposed through the opening of the first barrier layer BAR1 may be electrically connected to the bump 220 of the circuit board 200 through the conductive ink pattern 400.

The circuit board 200 may include a base 210 and a bump 220 disposed on the base 210.

The bump 220 may be disposed on a lower side of the base 210 of the circuit board 200. As illustrated in FIG. 7B, a plurality of bumps 220 may be formed on the lower side of the base 210 and disposed along the first direction DR1.

At least a portion of the bump 220 may be disposed on the pad electrode PDE. Although not illustrated, the bump 220 may be attached onto the pad electrode PDE and the barrier layer BAR through a non-conductive film NCF (see FIG. 22).

As illustrated in FIG. 7A, one end portion 220a of the bump 220 may more protrude than one end portion 210a of the base 210. For example, the other end portion of the bump 220 in the second direction DR2 may more protrude than the other end portion of the base 210 in the second direction DR2 by a first distance D1. Accordingly, the bump 220 may include a protruding portion PRT that does not overlap the base 210. At least a portion of the protruding portion PRT of the bump 220 may be disposed on the pad electrode PDE. As an example, the first distance D1 may be 1.2 to 2 times a second distance D2, which is a distance of an area in which the protruding portion PRT of the bump 220 and the pad electrode PDE overlap in the second direction DR2.

The base 210 of the circuit board 200 may completely cover the lower surface of the bump 220 before a cutting process using a laser LS. A portion of the base 210 may be cut by the laser LS emitted from a laser head LSH, and a cut portion 210_R may be removed. Accordingly, the protruding portion PRT of the bump 220 may be formed.

The pad electrode PDE and the bump 220 of the circuit board 200 may be bonded to each other by the conductive ink pattern 400. For example, the conductive ink pattern 400 may be disposed on the bump 220 and the pad electrode PDE. The conductive ink pattern 400 may be in direct contact with the pad electrode PDE and the bump 220.

In some embodiments, the conductive ink pattern 400 may completely cover lower and side surfaces of the bump 220 and the pad electrode PDE. As an example, a width 400_W of the conductive ink pattern 400 in the first direction DR1 may be greater than a width PDE_W of the pad electrode PDE and a width 220_W of the bump 220. As a result, a contact area of the conductive ink pattern 400 with the bump 220 and the pad electrode PDE increases, thereby increasing adhesion.

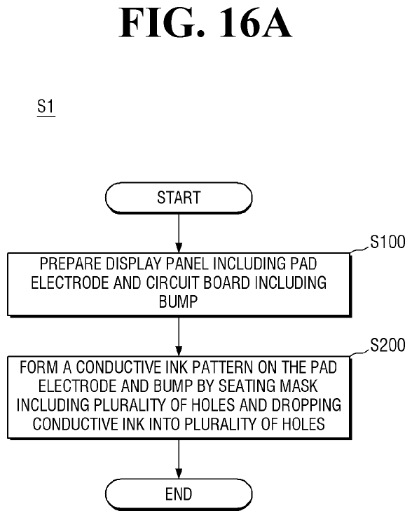

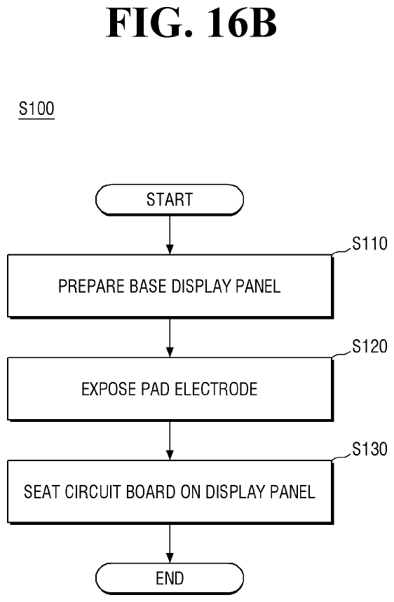

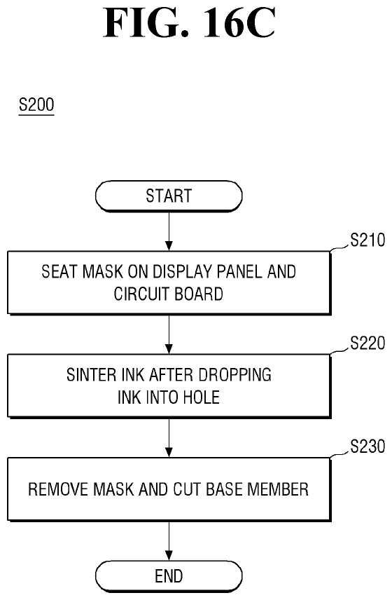

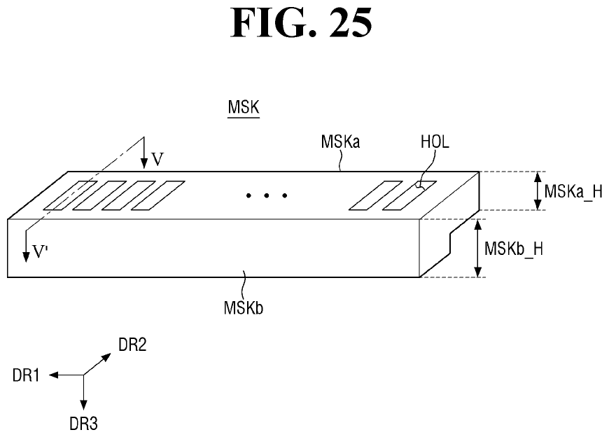

A shape of the side surface of the conductive ink pattern 400 may be the same as a shape of a partition wall inside a hole HOL (see FIG. 25) of a mask MSK (see FIG. 25) in a method S1 for manufacturing a display device (see FIG. 16A) to be described later. In some embodiments, the lower surface of the conductive ink pattern 400 may have a shape having a concave central portion. As the conductive ink pattern 400 is formed by sintering conductive ink CDI (see FIG. 27) in the method S1 for manufacturing a display device to be described later, the conductive ink pattern 400 may have an edge higher than the central portion along the partition wall of the mask MSK by surface tension.

Hereinafter, other embodiments of the display device according to an embodiment will be described. In the following embodiments, the same components as those of the above-described embodiment will be denoted by the same reference numerals, and an overlapping description thereof will be omitted or simplified and differences will be mainly described.

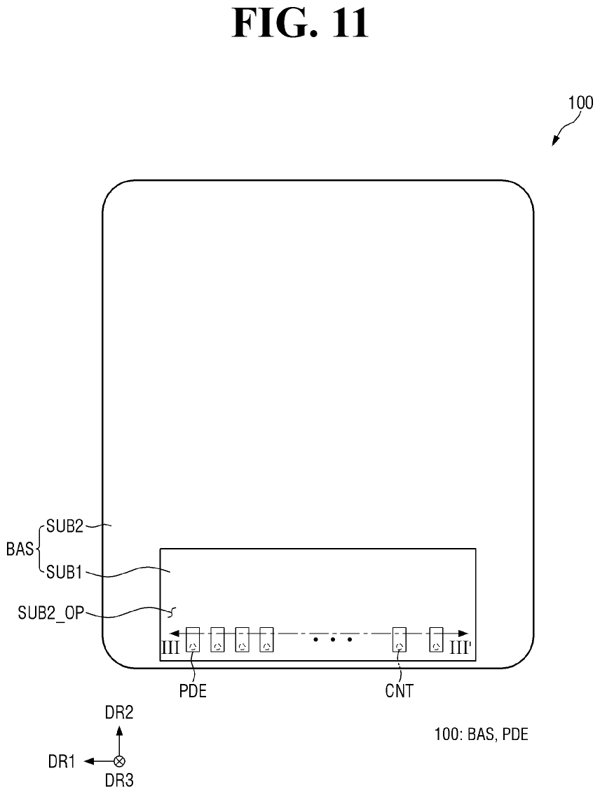

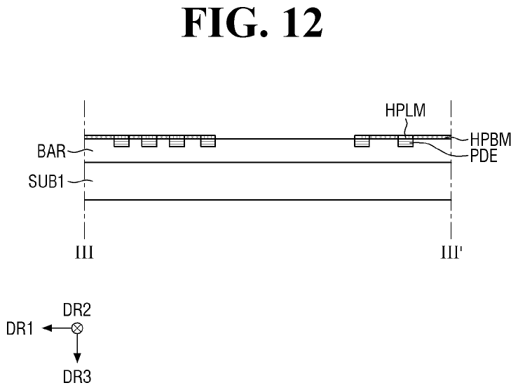

FIG. 11 is a plan view illustrating a lower surface of a display panel according to another embodiment. FIG. 12 is a cross-sectional view taken along line III-III′ of FIG. 11. FIG. 12 is an upside-down view. FIGS. 11 and 12 are views that illustrate only the display panel 100, and do not illustrate the circuit board 200, the driving chip 300, and the conductive ink pattern 400.

Referring to FIGS. 11 and 12, a display device 1 according to this embodiment is different from the display device 1 according to an embodiment with reference to FIGS. 2 and 9 and the like in that the lower surface of the pad electrode PDE is subjected to hydrophilic treatment and the lower surface of the first substrate SUB1 adjacent to the pad electrode PDE is subjected to hydrophobic treatment.

More specifically, the lower surface of the pad electrode PDE of the display device 1 according to the present embodiment may be subjected to hydrophilic treatment, and the lower surface of the first substrate SUB1 adjacent to the pad electrode PDE may be subjected to hydrophobic treatment. As an example, the lower surface of the pad electrode PDE may be subjected to surface pretreatment using a plasma gas containing hydrophilic molecules such as oxygen, argon, or nitrogen, and the lower surface of the first substrate SUB1 adjacent to the pad electrode PDE may be subjected to surface pretreatment using a plasma gas containing hydrophobic molecules such as fluorocarbon. Accordingly, a hydrophilic membrane HPLM may be formed on the pad electrode PDE, and a hydrophobic membrane HPBM may be formed on the first substrate SUB1 on which the pad electrode PDE is not positioned.

In some embodiments, in addition to the case where the lower surface of the pad electrode PDE is subjected to hydrophilic treatment and the lower surface of the first substrate SUB1 adjacent to the pad electrode PDE is subjected to hydrophobic treatment, only the lower surface of the pad electrode PDE is subjected to hydrophilic treatment and the lower surface of the first substrate SUB1 adjacent to the pad electrode PDE is not subjected to hydrophobic treatment, or only the lower surface of the first substrate SUB1 adjacent to the pad electrode PDE may be subjected to hydrophobic treatment, and the lower surface of the pad electrode PDE may not be subjected to hydrophilic treatment.

In another embodiment, as illustrated in FIG. 12, when the barrier layer BAR is included, a lower surface of the barrier layer BAR adjacent to the pad electrode PDE may be subjected to hydrophobic treatment.

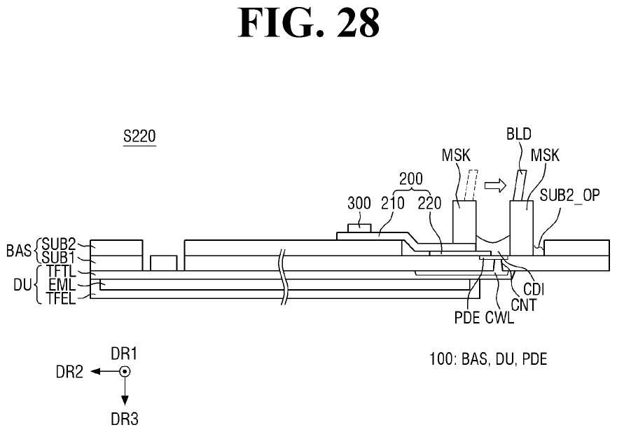

In the display device 1 according to the present embodiment, as the lower surface of the pad electrode PDE is subjected to hydrophilic treatment and the lower surface of the first substrate SUB1 adjacent to the pad electrode PDE is subjected to hydrophobic treatment, the conductive ink CDI (see FIGS. 27 and 28), which is also hydrophilic, may be seated on the pad electrode PDE even when the mask MSK (see FIG. 25) is partially misaligned in the method S1 (see FIG. 16A) for manufacturing a display device to be described later.

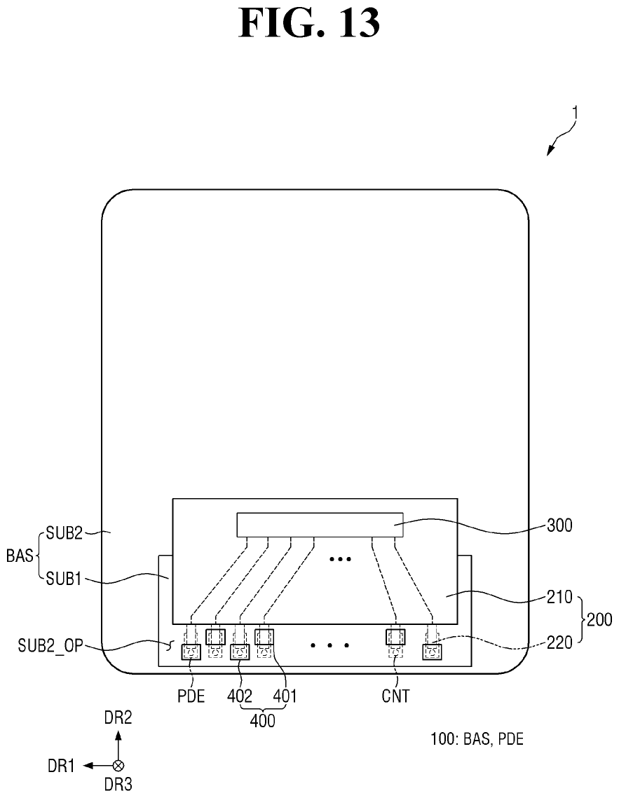

FIG. 13 is a plan view illustrating a lower surface of a display device according to still another embodiment.

Referring to FIGS. 13, a display device 1 according to still another embodiment is different from the display device 1 according to an embodiment described with reference to FIG. 2 and the like in that the plurality of conductive ink patterns 400 adjacent along the first direction DR1 are alternately disposed in the second direction DR2.

More specifically, the conductive ink pattern 400 of the display device 1 according to still another embodiment may cover only a portion of the lower surfaces of the pad electrode PDE and the bump 220 in a plan view. As an example, a length of the conductive ink pattern 400 in the second direction DR2 may be shorter than lengths of the pad electrode PDE and the bump 220 in the second direction DR2.

The plurality of conductive ink patterns 400 may be alternately disposed in the second direction DR2 while the plurality of conductive ink patterns 400 are adjacent to each other along the first direction DR1. For example, the conductive ink pattern 400 may include a plurality of first conductive ink patterns 401 positioned at even-numbered positions in the first direction DR1 and a plurality of second conductive ink patterns 402 positioned at odd-numbered positions in the first direction DR1. The first conductive ink pattern 401 may be disposed closer to the base 210 in the second direction DR2 than the second conductive ink pattern 402. In some embodiments, the first conductive ink patterns 401 and the second conductive ink patterns 402 may not overlap in the first direction DR1 and the second direction DR2.

According to the display device 1 according to the present embodiment, as the plurality of conductive ink patterns 400 adjacent to each other along the first direction DR1 are alternately disposed in the second direction DR2, it is possible to minimize an occurrence of a short circuit between the plurality of conductive ink patterns 400 adjacent to each other.

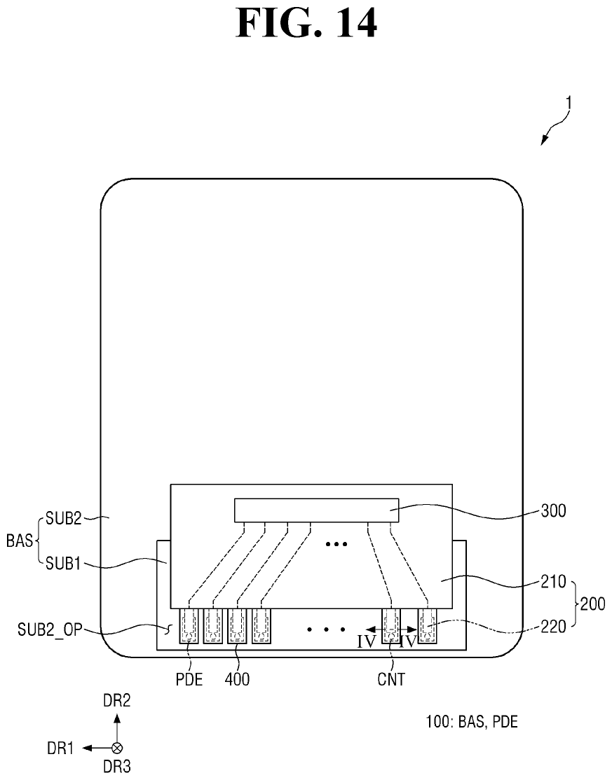

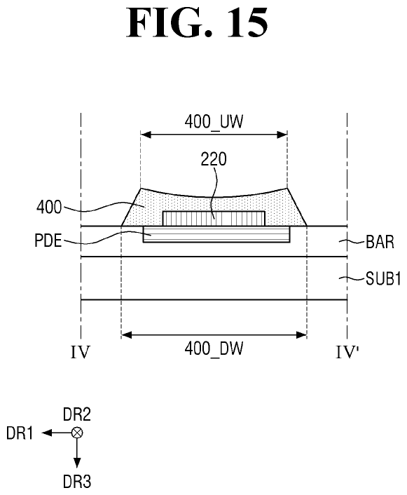

FIG. 14 is a plan view illustrating a lower surface of a display device according to still another embodiment. FIG. 15 is a cross-sectional view taken along line IV-IV′ of FIG. 14. FIG. 15 is an upside-down view.

Referring to FIGS. 14 and 15, a display device 1 according to still another embodiment is different from the display device 1 according to an embodiment described with reference to FIGS. 2 and 9 and the like in that a width 400_UW of the lower surface of the conductive ink pattern 400 is narrower than a width 400_DW of the upper surface thereof.

More specifically, in the display device 1 according to still another embodiment, the width 400_UW of the lower surface of the conductive ink pattern 400 may be narrower than the width 400_DW of the upper surface thereof. A side surface of the conductive ink pattern 400 may be inclined at a predetermined angle with respect to the third direction DR3. The width 400_UW of the lower surface and the width 400_DW of the upper surface of the conductive ink pattern 400 may refer to the shortest distances measured along a straight line parallel to the first direction DR1.

According to the display device 1 according to the present embodiment, by making the width 400_UW of the lower surface of the conductive ink pattern 400 narrower than the width 400_DW of the upper surface thereof, it is possible to prevent the conductive ink pattern 400 from being detached from the first substrate SUB1 or the barrier layer BAR or impact from being applied to the conductive ink pattern 400 when the mask MSK (see FIG. 25) is removed in the third direction DR3, that is, an upward direction in the method S1 (see FIG. 16A) for manufacturing a display device to be described later.

Hereinafter, a method for manufacturing a display device according to an embodiment will be described.

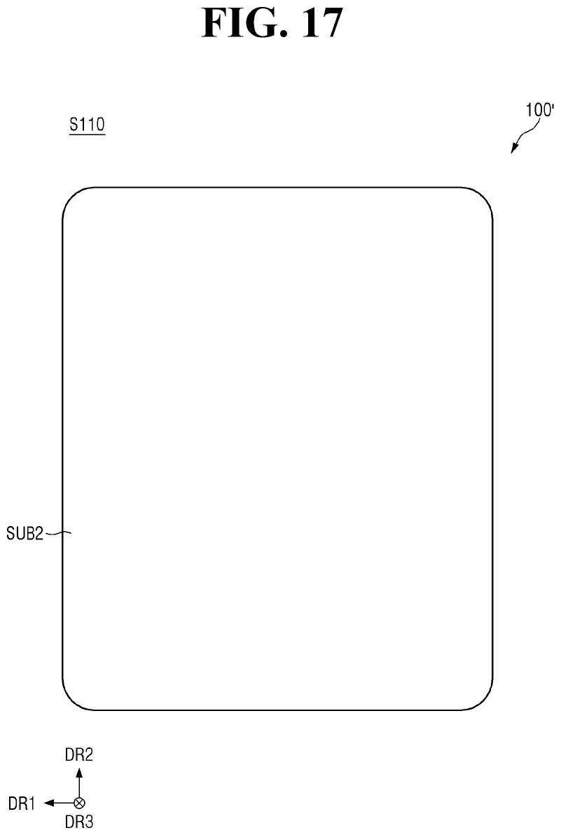

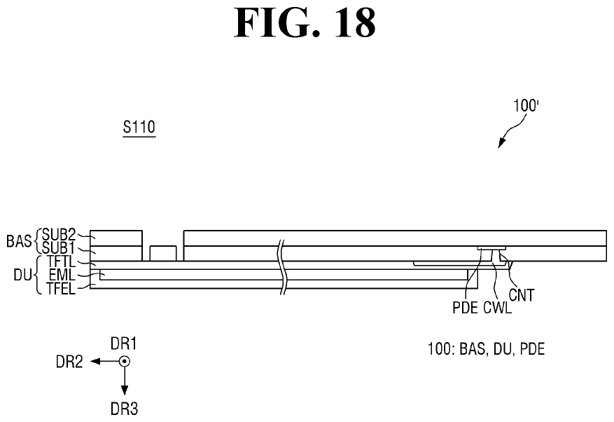

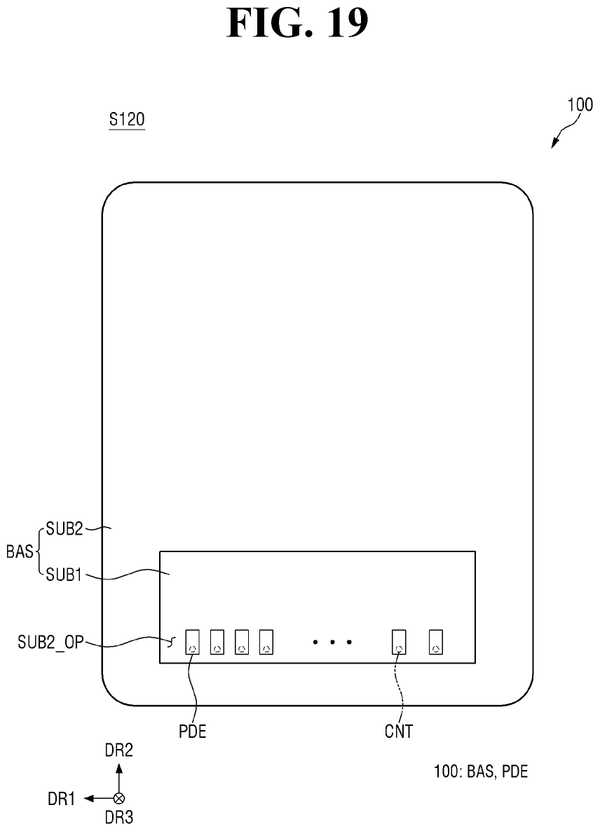

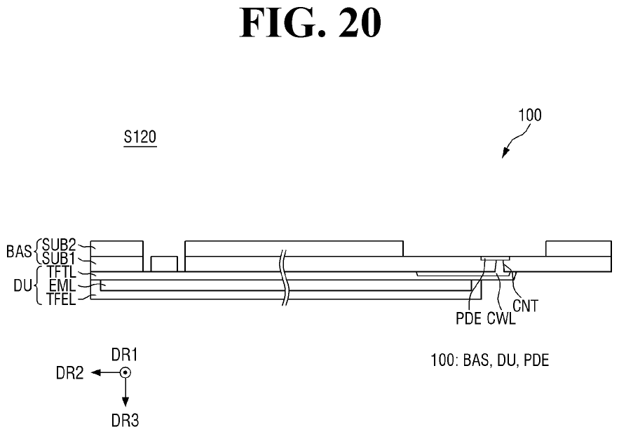

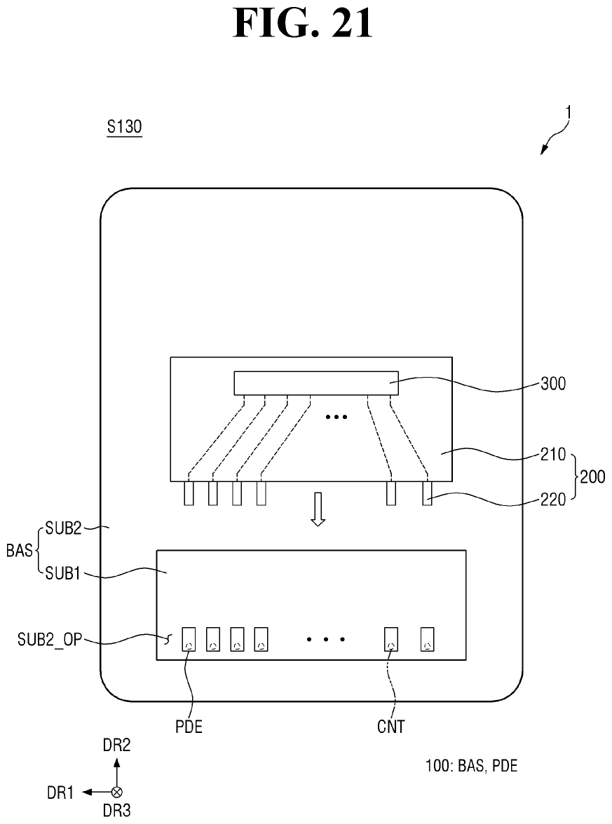

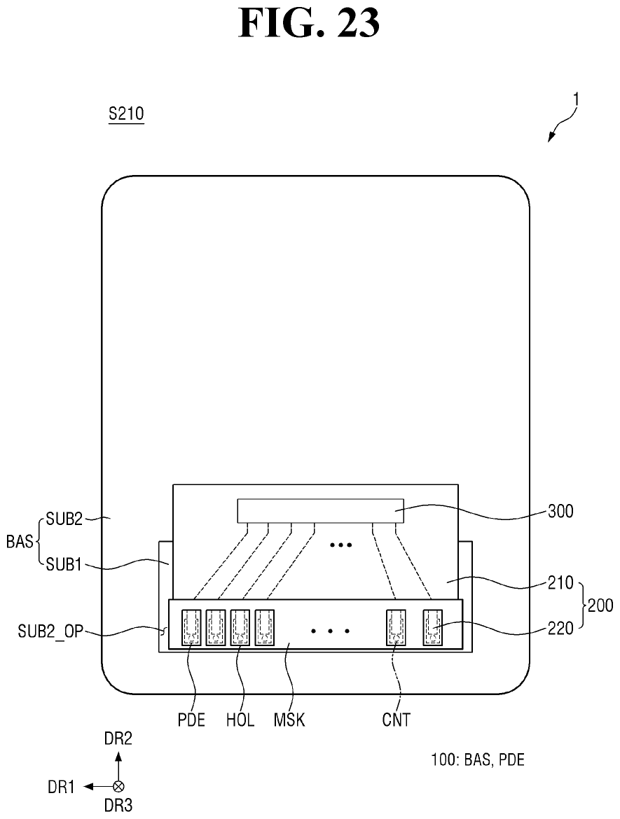

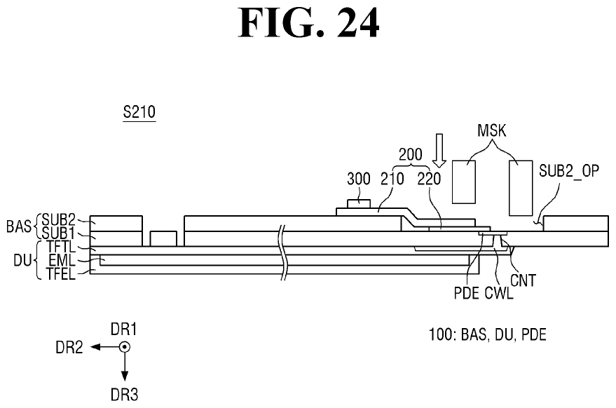

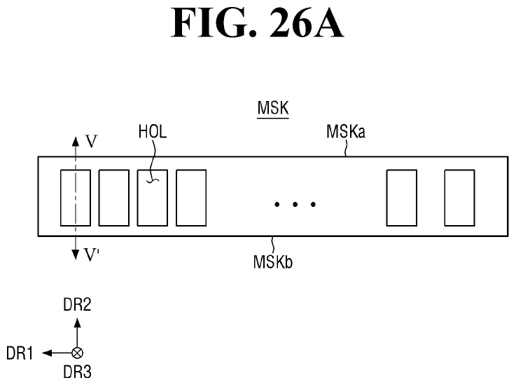

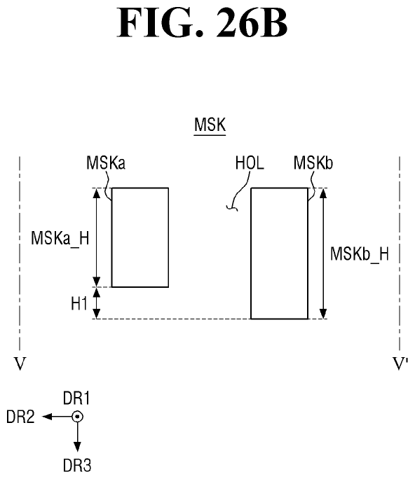

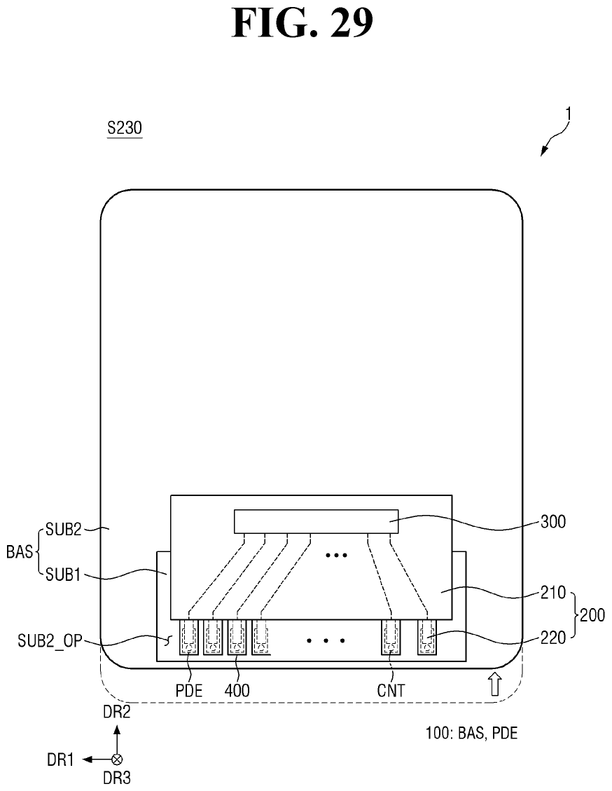

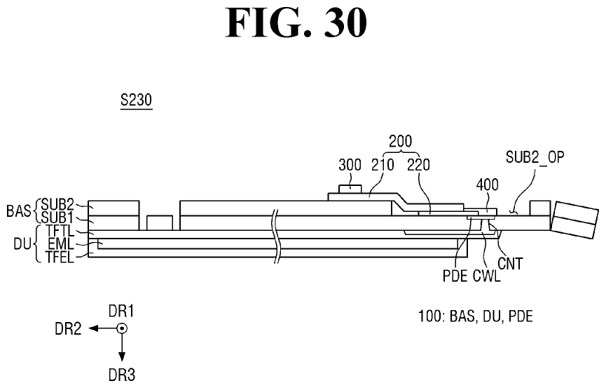

FIGS. 16A, 16B, and 16C are flowcharts illustrating a method for manufacturing a display device according to an embodiment. FIGS. 17 and 18 are a plan view and a cross-sectional view illustrating step S110 of FIG. 16B, respectively. FIGS. 19 and 20 are a plan view and a cross-sectional view illustrating step S120 of FIG. 16B, respectively. FIGS. 21 and 22 are a plan view and a cross-sectional view illustrating step S130 of FIG. 16B, respectively. FIGS. 23 and 24 are a plan view and a cross-sectional view illustrating step S210 of FIG. 16C, respectively. FIG. 25 is a perspective view illustrating a mask used in the method for manufacturing a display device according to an embodiment. FIGS. 26A and 26B are a plan view and a cross-sectional view illustrating the mask used in the method for manufacturing a display device according to an embodiment. FIGS. 27 and 28 are a plan view and a cross-sectional view illustrating step S220 of FIG. 16C, respectively. FIGS. 29 and 30 are a plan view and a cross-sectional view illustrating step S230 of FIG. 16C, respectively. FIGS. 18, 20, 22, 24, 26B, 28, and 30 are upside-down views. Even though the following method for manufacturing the display device is described in a situation that the elements of the display device 1 are upside-down, hereinafter, the same terminologies for the surfaces (e.g., upper surface, lower surface) of the elements of the display device 1 as those used for the embodiments above will still be used to keep consistency, while upper and lower surfaces of mask MSK and conductive ink CDI are defined using a different orientation from the elements of the display device 1.

Referring to FIGS. 17 to 30 in addition to FIGS. 16A, 16B, and 16C, a method S1 for manufacturing a display device according to an embodiment may include an operation (S100) of preparing a display panel and a circuit board and an operation (S200) of forming a conductive ink pattern.

Referring to FIG. 16B, the operation (S100) of preparing of the display panel and the circuit board may include an operation (S110) of preparing a base display panel, an operation (S120) of exposing pad electrodes, and an operation (S130) of seating the circuit board on the display panel.

In the operation (S110) of preparing the base display panel, a base display panel 100′ may be a display panel 100 in which the opening SUB2_OP of the second substrate SUB2 is not formed in any one of the display panels 100 according to the embodiments of FIGS. 1 to 15. The pad electrode PDE of the base display panel 100′ may not be exposed.

In the operation (S120) of exposing the pad electrode, an opening SUB2_OP may be formed on the lower surface of the second substrate SUB2 of the base display panel 100′. In an embodiment, the opening SUB2_OP may be formed through a laser cutting process in a state in which the display panel 100 is turned over, that is, in a state in which the display layer DU is positioned on the lower side of the base member BAS.

The base display panel 100′ on which the opening SUB2_OP is formed may be the same as the display panel 100 according to the embodiments of FIGS. 1 to 15. The pad electrode PDE may be exposed to the outside through the opening SUB2_OP.

In the operation (S130) of seating the circuit board on the display panel, the circuit board 200 may be seated on the other surface of the first substrate SUB1 in the state in which the display panel 100 is turned over.

A non-conductive film NCF may be attached to a lower portion of the bump 220 of the circuit board 200. The bump 220 may be attached to the lower surface of the pad electrode PDE and the lower surface of the first substrate SUB1 through the non-conductive film NCF. In another embodiment, when a barrier layer BAR is included, the bump 220 may be attached to the lower surfaces of the pad electrode PDE and the barrier layer BAR.

By using the non-conductive film NCF in the method S1 for manufacturing a display device according to the present embodiment, the bump 220 may be attached to the display panel 100 in a low temperature and low pressure state. Thereafter, a conductive ink pattern 400 may be formed to electrically connect the bump 220 and the pad electrode PDE to each other.

In the operation (S200) of forming the conductive ink pattern, the conductive ink pattern 400 may be formed on the pad electrode PDE and the bump 220 by dropping conductive ink CDI onto a plurality of holes HOL using a mask MSK including the plurality of holes HOL.

Referring to FIG. 16C, the operation (S200) of forming the conductive ink pattern may include an operation (S210) of seating the mask, an operation (S220) of dropping and sintering ink, and an operation (S230) of removing the mask and cutting the base member.

In the operation (S210) of seating the mask, the mask MSK may be seated on the circuit board 200 and the first substrate SUB1. A lower surface of the circuit board 200 may be positioned higher than a lower surface of the first substrate SUB1 due to a thickness of the circuit board 200. A lower surface of the mask MSK may adhere to the lower surface of the circuit board 200 and the lower surface of the first substrate SUB1. When a barrier layer BAR is included, the mask MSK may be seated on the circuit board 200 and the barrier layer BAR.

Referring to FIGS. 25 to 26B, the mask MSK may include a plurality of holes HOL disposed along the first direction DR1. The plurality of holes HOL may overlap the pad electrode PDE and the bump 220 in the third direction DR3.

The mask MSK may include a first surface MSKa positioned on one side of the hole HOL in the second direction DR2 and a second surface MSKb positioned on the other side of the hole HOL in the second direction DR2.

A vertical length MSKa_H of the first surface MSKa in the third direction DR3 may be smaller than a vertical length MSKb_H of the second surface MSKb in the third direction DR3 by a first vertical-length difference H1. A size of the first vertical-length difference H1 may be equal to a height difference between the lower surface of the circuit board 200 and the lower surface of the first substrate SUB1 positioned in the opening SUB2_OP.

According to the method S1 for manufacturing a display device according to the present embodiment, by forming the first vertical-length difference H1 between the first surface MSKa and the second surface MSKb of the mask MSK by the height difference between the lower surface of the circuit board 200 and the lower surface of the first substrate SUB1, the mask MSK may adhere to the display panel 100. As a result, it is possible to prevent the conductive ink CDI dropped into the hole HOL from escaping to the outside of the hole HOL or from invading an adjacent hole HOL.

In the method S1 for manufacturing a display device according to the present embodiment, the operation (S220) of dropping and sintering the ink into the hole may be an operation of dropping ink into the hole HOL through a screen printing method.

The mask MSK, which is a thin metal plate, may be a type of fine metal mask. In an embodiment, the mask MSK may include SUS metal. In another embodiment, the mask MSK may include Invar metal. When the mask MSK includes Invar metal, the mask MSK may have a low coefficient of thermal expansion. Accordingly, a size of the hole HOL, which is hardly affected by an external temperature, may be maintained to be constant.

In the operation (S220) of dropping and sintering the ink into the hole, the conductive ink CDI may be applied on the upper surface of the mask MSK.

In an embodiment, the conductive ink CDI may be positioned on one side or the other side of the hole HOL in the second direction DR2. It is illustrated in FIG. 27 that the conductive ink CDI extends along the first direction DR1 and is positioned on one side of an entirety of the plurality of holes HOL, but the conductive ink CDI is not limited thereto. For example, a plurality of conductive inks CDI may be formed and positioned on one or the other side of each of the plurality of holes HOL.

In another embodiment, the conductive ink CDI may be applied to overlap the plurality of holes HOL. For example, the conductive ink CDI may be applied to most of the upper surface of the mask MSK while overlapping the entirety of the plurality of holes HOL. When the conductive ink CDI has high viscosity, the conductive ink CDI may not be dropped into the hole HOL until an external force is applied thereto due to a cohesive force of the ink.

The conductive ink CDI may have a relatively high viscosity. For example, the viscosity of the conductive ink CDI may be approximately 5,000 cps to 20,000 cps. In the method S1 for manufacturing a display device according to the present embodiment, since the conductive ink CDI having high viscosity is used, spreadability of the ink is low, and thus the conductive ink CDI may not be dropped into the hole HOL until the external force is applied thereto.

The conductive ink CDI may be hydrophilic. The conductive ink CDI may include a conductive metal material. As an example, the conductive ink CDI may include at least one of silver (Ag) nanoparticle ink, copper (Cu) nanoparticle ink, and metal organic decomposition ink.

The conductive ink CDI may have a metal content of approximately 40 weight percents (wt %) to 90 wt %. Preferably, the conductive ink CDI may have a metal content of approximately 50 wt % to 90 wt %. As a result, even after the conductive ink CDI is sintered inside the hole HOL to become the conductive ink pattern 400, a shape thereof inside the hole HOL may be maintained as it is. When the conductive ink CDI has a metal content lower than 50 wt %, electrical conductivity may be weakened, and it may be difficult to maintain the shape of the conductive ink pattern 400 after the ink is sintered. When the conductive ink CDI has a metal content greater than 90 wt %, printability may be deteriorated.

A blade BLD may be positioned on the mask MSK. The blade BLD may be positioned on one side or the other side of the plurality of holes HOL with the conductive ink CDI interposed therebetween in the second direction DR2.

The blade BLD may move along the second direction DR2 while applying pressure on the mask MSK in the third direction DR3. As the blade BLD moves in the second direction DR2, misalignment in the first direction DR1 may be minimized. As a result, a short circuit defect between the adjacent pad electrodes PDE, the bump 220, and the conductive ink pattern 400 disposed along the first direction DR1 may be minimized.

The blade BLD may push the conductive ink CDI in the second direction DR2 and apply pressure in the third direction DR3 when passing through the plurality of holes HOL, thereby dropping the conductive ink CDI into the plurality of holes HOL. For example, the blade BLD may push the conductive ink CDI while moving from one side to the other side or from the other side to one side in the second direction DR2, that is, from top to bottom or from bottom to top in the drawing. The conductive ink CDI may be dropped into the holes HOL by the pressure applied to the mask MSK in the third direction DR3 by the blade BLD when the blade BLD passes through the plurality of holes HOL.

The conductive inks CDI dropped into the plurality of holes HOL may be disposed to be spaced apart from each other. The conductive ink CDI may be sintered inside the hole HOL while maintaining the same shape as the inside of the hole HOL to form the conductive ink pattern 400. For example, in an embodiment, the upper surface of the conductive ink CDI may have a shape having a concave central portion by surface tension acting between the conductive ink CDI and the partition wall of the mask MSK inside the hole HOL.

According to the method S1 for manufacturing a display device according to the present embodiment, the conductive inks CDI respectively dropped on the plurality of pad electrodes PDE may be spaced apart from each other by the plurality of holes HOL of the mask MSK. As a result, it is possible to prevent a short circuit between adjacent conductive ink patterns 400 formed by sintering the conductive inks CDI.

In the operation (S230) of removing the mask, after the conductive ink CDI is sintered, the mask MSK may be detached and removed from the display panel 100 and the circuit board 200. After the mask MSK is removed, the conductive ink pattern 400 may be formed in an area where the hole HOL is positioned.

After the mask MSK is removed, a portion of an end portion of the base member BAS of the display panel 100 may be cut. According to the method S1 for manufacturing a display device according to the present embodiment, an extra length may be left at the end portion of the base member BAS in consideration of an attachment tolerance of the mask MSK and a cutting tolerance of the opening SUB2_OP during the manufacturing process. As the extra length is cut after the manufacturing process is finished, a dead space of the display device 1 may be minimized.

Hereinafter, a method for manufacturing a display device according to another embodiment will be described.

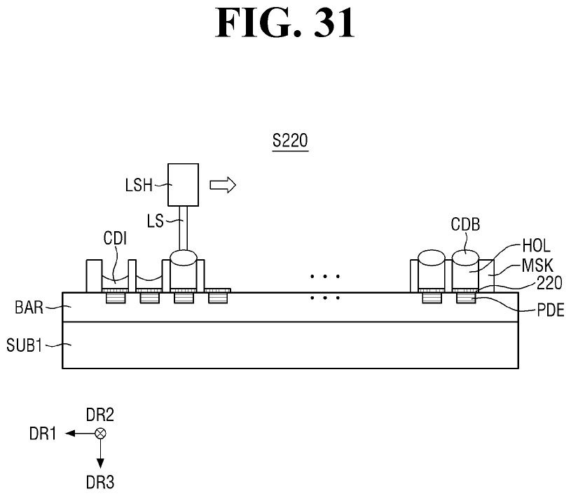

FIG. 31 is a cross-sectional view illustrating step S220 in a method for manufacturing a display device according to another embodiment. FIG. 31 is an upside-down view.

Referring to FIG. 31, a method S1 for manufacturing a display device according to another embodiment is different from the method S1 for manufacturing a display device according to an embodiment described with reference to FIG. 27 and the like in that the conductive ink CDI is dropped using a laser LS instead of the blade BLD.

More specifically, in the operation (S220) of dropping and sintering the ink into the hole, a conductive ball CDB may be applied on the upper surface of the mask MSK. For example, the conductive balls CDB may be interposed in each of the plurality of holes HOL.

A laser head LSH may be positioned on the mask MSK. The laser head LSH may irradiate a laser LS to the conductive ball CDB while moving in the first direction DR1.

The conductive ball CDB irradiated with the laser LS may be melted or dissolved in the form of conductive ink CDI by heat. The melted or dissolved conductive ink CDI may be dropped into the hole HOL.

In some embodiments, the laser head LSH may shorten a sintering time of the ink by applying wind to the conductive ink CDI.

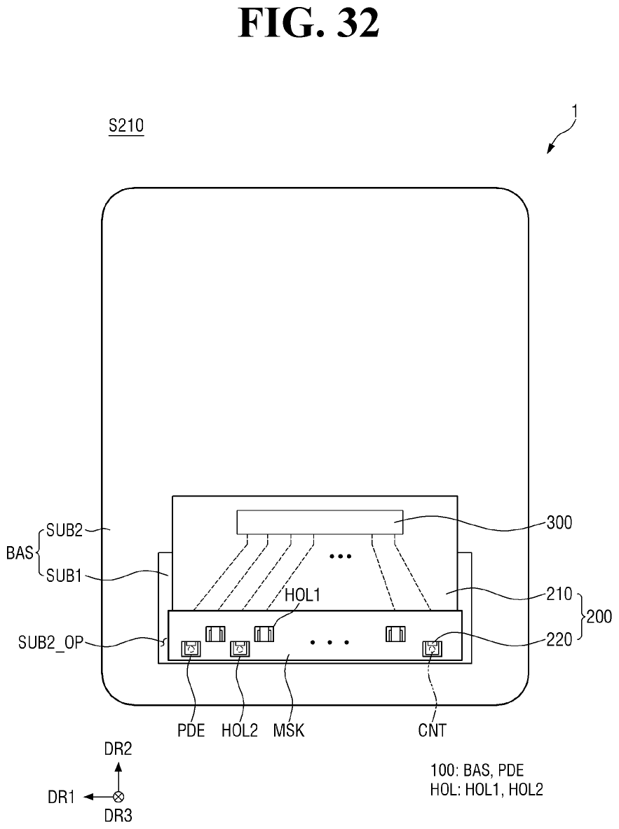

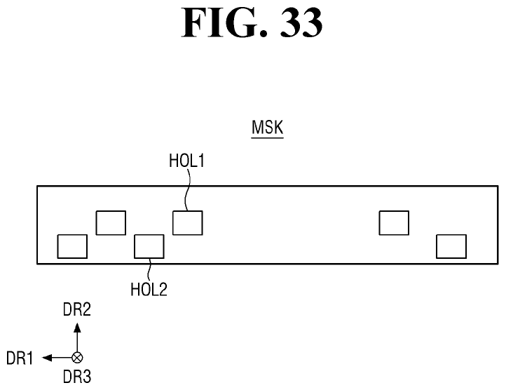

FIG. 32 is a plan view illustrating step S210 in the method for manufacturing a display device according to still another embodiment. FIG. 33 is a plan view illustrating a mask of FIG. 32.

Referring to FIGS. 32 and 33, a method S1 for manufacturing a display device according to still another embodiment is different from the method S1 for manufacturing a display device according to an embodiment described with reference to FIG. 23 and the like in that the plurality of holes HOL adjacent to each other along the first direction DR1 are alternately disposed in the second direction DR2.

More specifically, the hole HOL of the mask MSK used in the method S1 for manufacturing a display device according to the present embodiment may overlap only a portion of the lower surfaces of the pad electrode PDE and the bump 220. As an example, a length of the hole HOL in the second direction DR2 may be shorter than lengths of the pad electrode PDE and the bump 220 in the second direction DR2.

The plurality of holes HOL may be alternately disposed in the second direction DR2 with the plurality of holes HOL adjacent to each other along the first direction DR1. For example, the plurality of holes HOL may include a plurality of first holes HOL1 positioned at even-numbered positions in the first direction DR1 and a plurality of second holes HOL2 positioned at odd-numbered positions in the first direction DR1. The first hole HOL1 may be disposed closer to the base 210 in the second direction DR2 than the second hole HOL2. In some embodiments, the first holes HOL1 and the second holes HOL2 may not overlap in the first direction DR1 and the second direction DR2.

According to the method S1 for manufacturing a display device according to the present embodiment, as the plurality of holes HOL adjacent to each other along the first direction DR1 are alternately disposed in the second direction DR2, it is possible to minimize an occurrence of a short circuit between the plurality of conductive ink patterns 400 adjacent to each other.

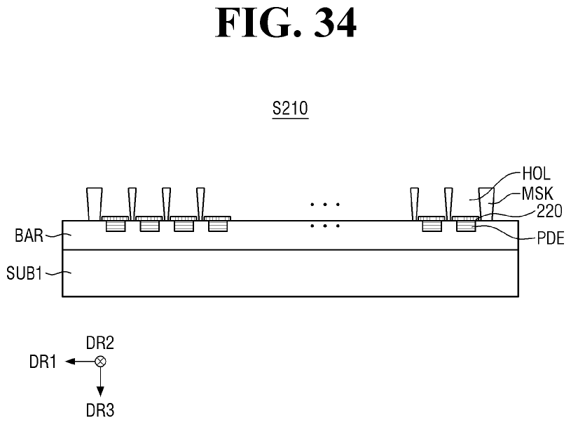

FIG. 34 is a cross-sectional view illustrating step S210 in the method for manufacturing a display device according to still another embodiment. FIG. 31 is an upside-down view.

Referring to FIG. 34, a method S1 for manufacturing a display device according to still another embodiment is different from the method S1 for manufacturing a display device according to an embodiment described with reference to FIG. 23 and the like in that a width of the hole HOL increases from the top to the bottom.

More specifically, in the method S1 for manufacturing a display device according to still another embodiment, the width of the hole HOL may increase from the top to the bottom of the hole HOL. A side surface of the hole HOL may be inclined at a predetermined angle with respect to the third direction DR3.

According to the method S1 for manufacturing a display device according to still another embodiment, by increasing the width of the hole HOL from the top to the bottom, it is possible to prevent the conductive ink pattern 400 from being detached from the first substrate SUB1 or the barrier layer BAR or from impact from being applied to the conductive ink pattern 400 when the mask MSK is removed in the third direction DR3, that is, an upward direction.

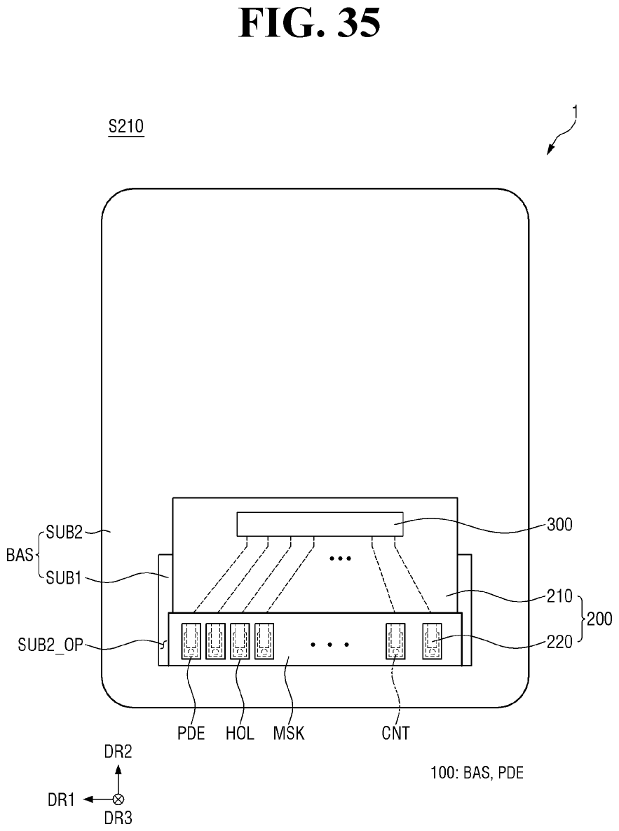

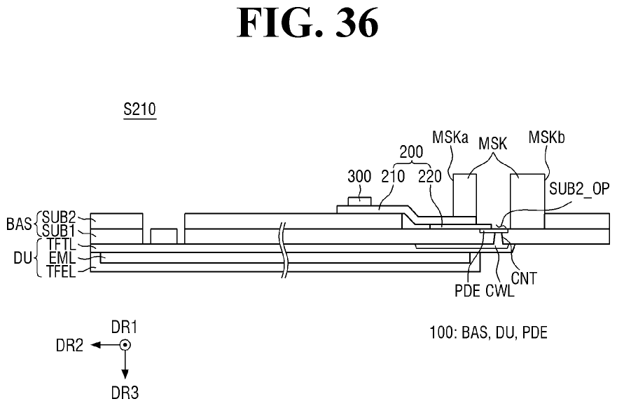

FIG. 35 is a plan view illustrating step S210 in the method for manufacturing a display device according to still another embodiment. FIG. 36 is a cross-sectional view illustrating step S210 in the method for manufacturing a display device according to an embodiment. FIG. 36 is an upside-down view.

Referring to FIGS. 35 and 36, a method S1 for manufacturing a display device according to still another embodiment is different from the method S1 for manufacturing a display device according to an embodiment described with reference to FIG. 23 and the like in that a boundary of one end portion of the mask MSK coincides with a boundary of the opening SUB2_OP.

More specifically, a boundary of one end portion of the mask MSK, that is, the other end portion in the second direction DR2 may coincide with a boundary of the opening SUB2_OP. For example, the second surface MSKb of the mask MSK may be in direct contact with an inner wall of the opening SUB2_OP.

According to the method S1 for manufacturing a display device according to the present embodiment, as the boundary of one end portion of the mask MSK coincides with the boundary of the opening SUB2_OP, misalignment of the mask MSK may be prevented when the blade BLD applies pressure on the mask MSK in the third direction DR3 and moves in the second direction DR2.

In concluding the detailed description, those skilled in the art will appreciate that many variations and modifications can be made to the preferred embodiments without substantially departing from the principles of the invention. Therefore, the disclosed preferred embodiments of the invention are used in a generic and descriptive sense only and not for purposes of limitation.

What is claimed is:

1. A display device comprising:
a first substrate;
a thin film transistor disposed on an upper surface of the first substrate;
a plurality of pad electrodes disposed under a lower surface of the first substrate;
a second substrate disposed under the lower surface of the first substrate and defining an opening therein exposing the plurality of pad electrodes;
a circuit board attached onto the plurality of pad electrodes exposed through the opening of the second substrate; and
a plurality of conductive ink patterns surrounding at least a side surface of the circuit board and being in contact with at least one of the plurality of pad electrodes,
wherein lower surfaces of the plurality of conductive ink patterns each have a shape having a concave central portion.

2. The display device of claim 1, wherein
the circuit board includes a base and a bump disposed on the base, and
one end portion of the bump protrudes from one end portion of the base.

3. The display device of claim 2,
wherein the plurality of conductive ink patterns cover at least a portion of the bump and the pad electrode, and electrically connect the bump and the pad electrode to each other.

4. The display device of claim 2,
wherein the plurality of conductive ink patterns completely cover lower and side surfaces of the bump.

5. The display device of claim 2, further comprising a non-conductive film disposed between the bump and the pad electrode.

6. The display device of claim 1,
wherein a width of each of the lower surfaces of the plurality of conductive ink patterns is narrower than a width of each of upper surfaces of the plurality of conductive ink patterns.

7. The display device of claim 6,
wherein side surfaces of the plurality of conductive ink patterns are inclined.

8. The display device of claim 1, further comprising a barrier layer disposed between the first substrate and the second substrate,
wherein the barrier layer exposes at least a portion of the pad electrode.

9. The display device of claim 1, wherein
a lower surface of each of the pad electrodes is hydrophilic, and
the lower surface of the first substrate adjacent to the pad electrode is hydrophobic.

10. The display device of claim 1,
wherein the plurality of conductive ink patterns are adjacent to each other along a first direction and alternately disposed in a second direction different from the first direction.

11. A method for manufacturing a display device, the method comprising:
preparing a display panel and a circuit board; and
forming a plurality of conductive ink patterns under the display panel and the circuit board by seating a mask defining a plurality of holes therein and dropping conductive ink into the plurality of holes,
wherein the display panel includes:
a first substrate;
a thin film transistor disposed on an upper surface of the first substrate;
a plurality of pad electrodes disposed under a lower surface of the first substrate; and
a second substrate disposed under the lower surface of the first substrate and defining an opening therein exposing the plurality of pad electrodes,
wherein the circuit board is attached onto the plurality of pad electrodes exposed through the opening of the second substrate,
the plurality of conductive ink patterns surround at least a side surface of the circuit board and is in contact with at least one of the plurality of pad electrodes, and
lower surfaces of the plurality of conductive ink patterns each have a shape having a concave central portion.

12. The method of claim 11, wherein the forming of the conductive ink patterns includes:
applying the conductive ink on the mask; and
pushing the conductive ink into the plurality of holes using a blade.

13. The method of claim 11, wherein the forming of the conductive ink patterns includes:
interposing a conductive ball in the plurality of holes; and
melting and dropping the conductive ball in a form of the conductive ink by irradiating the conductive ball with a laser.

14. The method of claim 11, wherein
the mask includes a first surface positioned on one side of the plurality of holes and a second surface positioned on an opposite side of the plurality of holes, and
a vertical length of the first surface is shorter than a vertical length of the second surface.

15. The method of claim 14,
wherein a vertical-length difference between the vertical length of the first surface and the vertical length of the second surface is equal to a height difference between a lower surface of the circuit board and the lower surface of the first substrate.

16. The method of claim 11,
wherein the plurality of holes are adjacent to each other along a first direction and alternately disposed in a second direction different from the first direction.

17. The method of claim 11,
wherein each of the plurality of holes has a wider width in a direction from top to bottom thereof.

18. The method of claim 11,
wherein a boundary of a bottom end portion of the mask coincides with a boundary of the opening.

19. The method of claim 11,
wherein the conductive ink includes at least one of silver (Ag) nanoparticle ink, copper (Cu) nanoparticle ink, and metal organic decomposition ink.

20. The method of claim 19,
wherein the conductive ink has a metal content of 50 weight percents (wt %) to 90 wt %.
